(19) United States
(12) Patent Application Publication
(10) Pub. No.: US 2026/0271570 A1
(43) Pub. Date: Sep. 10, 2026

(54) DISPLAY DEVICE

(71) Applicant: Sharp Display Technology Corporation, Kameyama City, Mie (JP)

(72) Inventors: Jun NISHIMURA, Kameyama City, Mie (JP); Yoshihito HARA, Kameyama City, Mie (JP); Masaki MAEDA, Kameyama City, Mie (JP); Yoshiharu HIRATA, Kameyama City, Mie (JP); Yohei TAKEUCHI, Kameyama City, Mie (JP); Tohru DAITOH, Kameyama City, Mie (JP)

(21) Appl. No.: 19/136,507

(22) PCT Filed: Dec. 27, 2022
(86) PCT No.: PCT/JP2022/048273

§ 371 Date: Jun. 6, 2025

(51) Int. Cl. H10K 59/131; H10D 30/67; H10K 59/121; H10K 59/80

(52) U.S. Cl. CPC H10K 59/1315; H10D 30/6733; H10D 30/6755; H10K 59/1213; H10K 59/871

(57) ABSTRACT

A TFT layer including a stack of, in sequence, a first metal film, a first inorganic insulating film, a second metal film, a second inorganic insulating film, and a third metal film includes a plurality of first wiring lines in the first metal film, a plurality of second wiring lines in the second metal film, and a plurality of third wiring lines in the third metal film. Between a pair of adjacent third wiring lines one end and another end in a width direction of each of the plurality of first wiring lines do not respectively partly overlap one end and another end in a width direction of a corresponding one of the plurality of second wiring lines corresponding to the one end and the another end of each of the plurality of first wiring lines.

### TECHNICAL FIELD

The disclosure relates to a display device.

### BACKGROUND ART

Attention has been recently drawn to self-emission organic EL display devices incorporating organic electroluminescence (hereinafter, also referred to as EL) elements, as display devices alternative to liquid crystal displays. Such an organic EL display device includes a plurality of thin-film transistors (hereinafter, also referred to as “TFTs”) provided for each subpixel, which is for performing image display. Here, to prevent leakage current, a double-gate structure, for instance, including gate electrodes provided over and under a semiconductor layer with gate insulating films interposed therebetween has been proposed as a typical structure of a TFT including a semiconductor layer and gate electrodes provided in the semiconductor layer with gate insulating films interposed therebetween.

For instance, Patent Literature 1 discloses a pixel TFT having a double-gate structure including the following: an oxide semiconductor layer; an upper gate electrode provided over the oxide semiconductor layer with a gate insulating layer interposed therebetween; and a lower gate electrode provided under the oxide semiconductor layer with a lower insulating layer interposed therebetween.

### Citation List

### Patent Literature

Patent Literature 1: Japanese Unexamined Patent Application Publication No. 2021-097126

### SUMMARY

### Technical Field

By the way, in a display device including a TFT with a double-gate structure including mutually overlapping first and second gate electrodes, when a first wiring line containing the same material and formed in the same layer as the lower first gate electrode overlap a second wiring line containing the same material and formed in the same layer as the upper second gate electrode, an inorganic insulating film covering the second wiring line has a large-stepped surface. Accordingly, a residue of a metal film, which constitutes third wiring lines, remains easily along the steps on the surface of the inorganic insulating film, and by way of the metal film's residue, a short circuit can be established between the third wiring lines adjacently provided and intersecting with the first and second wiring lines on the surface of the inorganic insulating film.

The disclosure has been made in view of the foregoing problem, and aims to prevent a short circuit between the third wiring lines intersecting with the first and second wiring lines on the inorganic insulating film covering the second wiring line overlapping the first wiring line.

### Solution to Problem

To achieve the above object, a display device according to the disclosure includes the following: a base substrate; and a thin-film transistor layer provided on the base substrate, and including a stack of, in sequence, a first metal film, a first inorganic insulating film, a second metal film, a second inorganic insulating film, and a third metal film. The thin-film transistor layer includes the following: a plurality of first wiring lines extending in parallel with each other in the first metal film; a plurality of second wiring lines extending in parallel with each other in the second metal film, and overlapping the plurality of first wiring lines; and a plurality of third wiring lines extending in parallel with each other in the third metal film, and intersecting with the plurality of first wiring lines and the plurality of second wiring lines. Between a pair of adjacent third wiring lines, one end and another end in a width direction of each of the plurality of first wiring lines do not respectively partly overlap one end and another end in a width direction of a corresponding one of the plurality of second wiring lines corresponding to the one end and the another end of each of the plurality of first wiring lines. The pair of adjacent third wiring lines are included in the plurality of third wiring lines.

### Advantageous Effect of Disclosure

The disclosure can prevent a short circuit between the third wiring lines intersecting with the first and second wiring lines on the inorganic insulating film covering the second wiring line overlapping the first wiring line.

### BRIEF DESCRIPTION OF DRAWINGS

FIG. 1 is a plan view of the schematic configuration of an organic EL display device according to a first embodiment of the disclosure.

FIG. 2 is a plan view of a display region of the organic EL display device according to the first embodiment of the disclosure.

FIG. 3 is a cross-sectional view of the display region of the organic EL display device according to the first embodiment of the disclosure.

FIG. 4 is an equivalent circuit diagram of a TFT layer constituting the organic EL display device according to the first embodiment of the disclosure.

FIG. 5 is a partial plan view of the TFT layer constituting the organic EL display device according to the first embodiment of the disclosure.

FIG. 6 is a cross-sectional view of the TFT layer taken along line VI-VI in FIG. 5.

FIG. 7 is a cross-sectional view of the TFT layer taken along line VII-VII in FIG. 5.

FIG. 8 is a cross-sectional view of an organic EL layer constituting the organic EL display device according to the first embodiment of the disclosure.

FIG. 9 is a partial plan view of a modification of the TFT layer constituting the organic EL display device according to the first embodiment of the disclosure, and corresponds to FIG. 5.

FIG. 10 is a partial plan view of a TFT layer constituting an organic EL display device according to a second embodiment of the disclosure, and corresponds to FIG. 5.

FIG. 11 is a cross-sectional view of the TFT layer taken along line XI-XI in FIG. 10.

FIG. 12 is a cross-sectional view of the TFT layer taken along line XII-XII in FIG. 10.

FIG. 13 is a partial plan view of a TFT layer constituting an organic EL display device according to a third embodiment of the disclosure, and corresponds to FIG. 5.

FIG. 14 is a cross-sectional view of the TFT layer taken along line XIV-XIV in FIG. 13.

FIG. 15 is a cross-sectional view of the TFT layer taken along line XV-XV in FIG. 13.

FIG. 16 is a partial plan view of a TFT layer constituting an organic EL display device according to a fourth embodiment of the disclosure, and corresponds to FIG. 5.

FIG. 17 is a cross-sectional view of the TFT layer taken along line XVII-XVII in FIG. 16.

FIG. 18 is a cross-sectional view of the TFT layer taken along line XVIII-XVIII in FIG. 16.

FIG. 19 is a partial plan view of a TFT layer constituting an organic EL display device according to a fifth embodiment of the disclosure, and corresponds to FIG. 5.

FIG. 20 is a cross-sectional view of the TFT layer taken along line XX-XX in FIG. 19.

FIG. 21 is a cross-sectional view of the TFT layer taken along line XXI-XXI in FIG. 19.

FIG. 22 is a partial plan view of a TFT layer constituting an organic EL display device according to a sixth embodiment of the disclosure, and corresponds to FIG. 5.

FIG. 23 is a cross-sectional view of the TFT layer taken along line XXIII-XXIII in FIG. 22.

FIG. 24 is a cross-sectional view of the TFT layer taken along line XXIV-XXIV in FIG. 22.

### DESCRIPTION OF EMBODIMENTS

The embodiments of the disclosure will be detailed on the basis of the drawings. It is noted that the disclosure is not limited to the following embodiments.

### First Embodiment

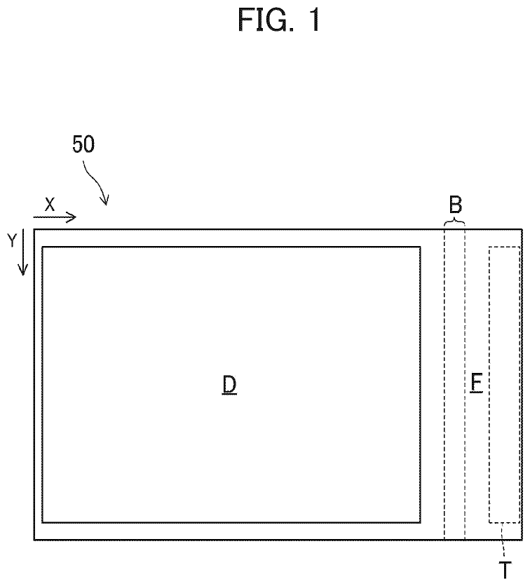

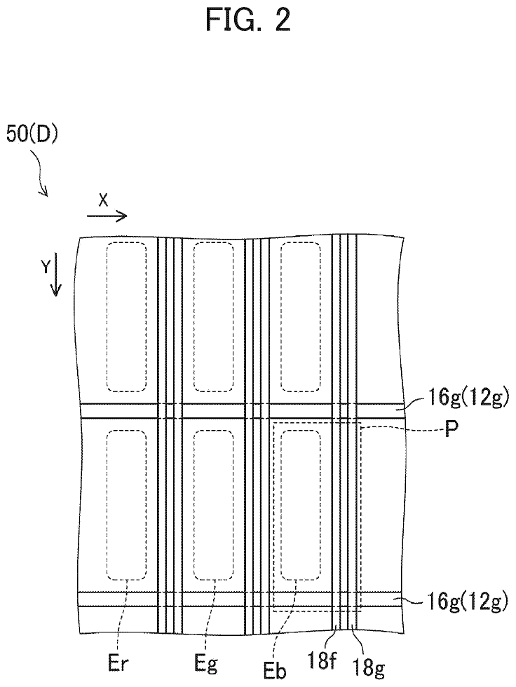

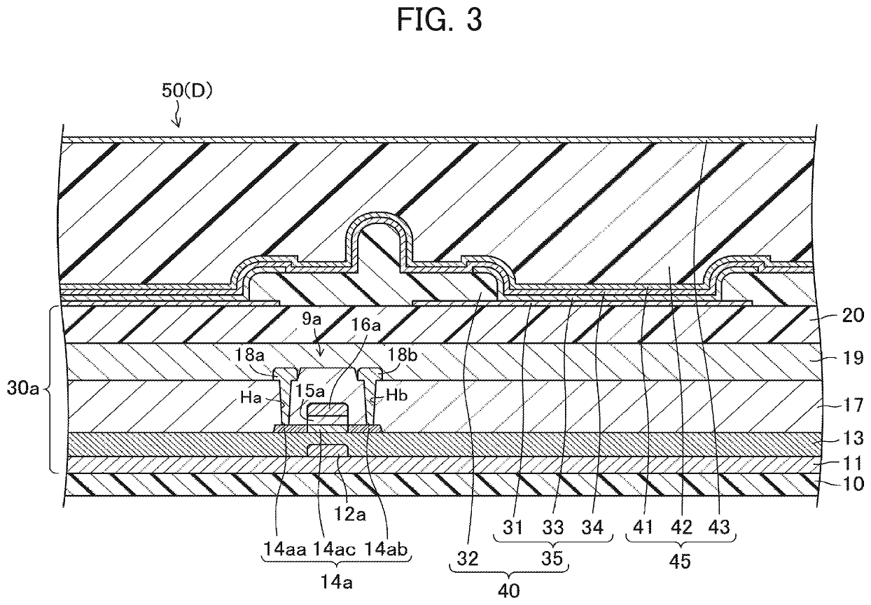

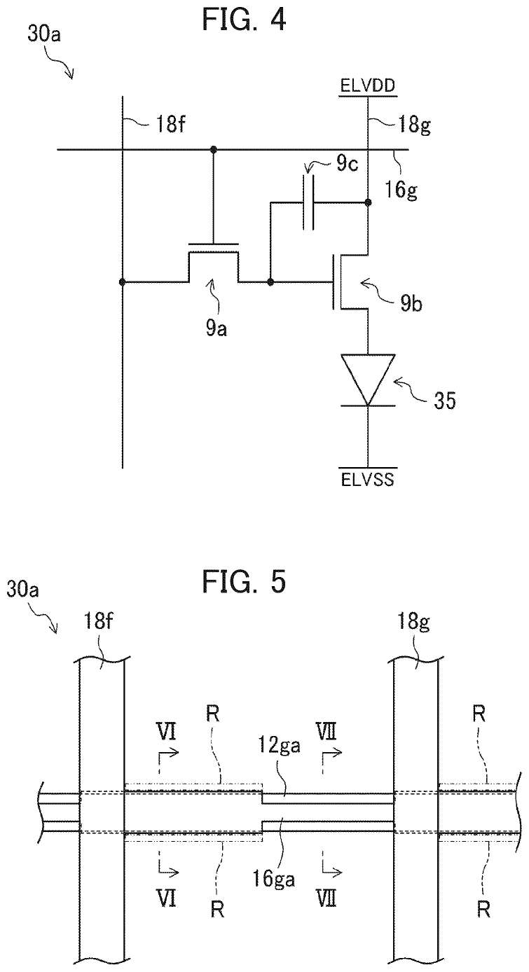

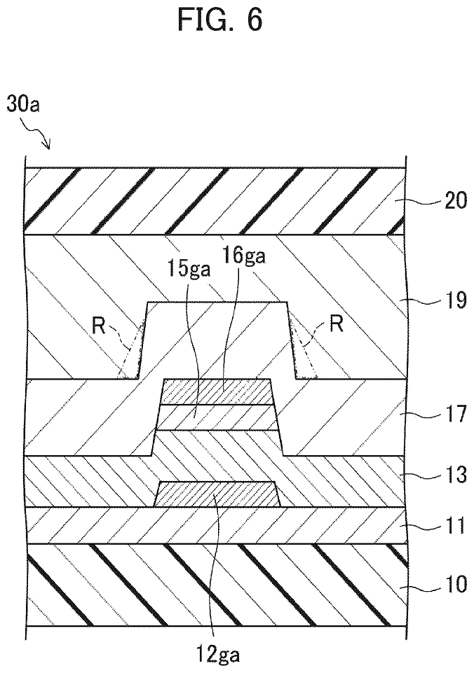

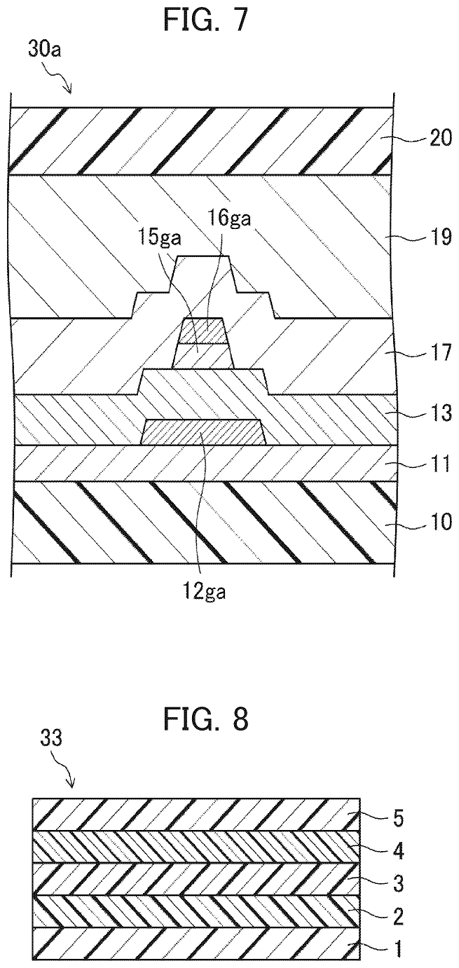

FIGS. 1 to 9 illustrate a display device according to a first embodiment of the disclosure. It is noted that each of the following embodiments will describe, by way of example, an organic EL display device including an organic EL element layer as a display device including a light-emitting element layer. Here, FIG. 1 is a plan view of the schematic configuration of an organic EL display device 50 according to this embodiment. In addition, FIGS. 2 and 3 are a plan view and a cross-sectional view of a display region D of the organic EL display device 50. In addition, FIG. 4 is an equivalent circuit diagram of a TFT layer 30a constituting the organic EL display device 50. In addition, FIG. 5 is a partial plan view of the TFT layer 30a. In addition, FIGS. 6 and 7 are cross-sectional views of the TFT layer 30a taken along lines VI-VI and VII-VII in FIG. 5. In addition, FIG. 8 is a cross-sectional view of an organic EL layer 33 constituting the organic EL display device 50.

As illustrated in FIG. 1, the organic EL display device 50 includes, for instance, the display region D shaped in a rectangle and provided for image display, and a frame region F provided around the display region D. It is noted that although this embodiment describes the rectangular display region D by way of example, this rectangular shape includes substantially rectangular shapes, such as a shape with an arc-shaped side, a shape with an arc-shaped corner, and a shape with part of a side being notched.

The display region D includes a plurality of subpixels P arranged in matrix, as illustrated in FIG. 2. Further, for instance, a subpixel P having a red emission region Er for red display, a subpixel P having a green emission region Eg for green display, and a subpixel P having a blue emission region Eb for blue display are provided in the display region D so as to be adjacent to one another, as illustrated in FIG. 2. It is noted that the display region D is configured such that for instance, three adjacent subpixels P having the red emission region Er, green emission region Eg, and blue emission region Eb constitute a single pixel.

The frame region F includes a terminal section T provided at the end in the positive X-direction in FIG. 1 so as to extend in one direction (the Y-direction of FIG. 1). The frame region F also includes, as illustrated in FIG. 1, a bending section B provided between the display region D and the terminal section T so as to extend in one direction (the Y-direction of the drawing); here, the bending section B is, for instance, 180° (U-shape) bendable about a bending axis, which is in the Y-direction of the drawing.

The organic EL display device 50 includes the following as illustrated in FIG. 3: a resin substrate 10 provided as a base substrate; the TFT layer 30a provided on the resin substrate 10; an organic EL element layer 40 provided as a light-emitting element layer on the TFT layer 30a; and a sealing film 45 provided on the organic EL element layer 40.

The resin substrate 10 contains an organic resin material, such as polyimide resin.

The TFT layer 30a includes the following as illustrated in FIG. 3: a base coat film 11 provided on the resin substrate 10; a plurality of first pixel TFTs 9a, a plurality of second pixel TFTs 9b (see FIG. 4), and a plurality of capacitors 9c (see FIG. 4) provided on the base coat film 11; and a protective insulating film 19 and a flattening film 20 provided sequentially on the first pixel TFTs 9a, second pixel TFTs 9b, and capacitors 9c.

As illustrated in FIG. 2, the TFT layer 30a includes a plurality of gate lines 16g provided as a plurality of second wiring lines so as to extend in parallel with each other in the X-direction of the drawing. As illustrated in FIG. 2, the TFT layer 30a also includes a plurality of lower gate lines 12g provided as a plurality of first wiring lines so as to overlap the plurality of gate lines 16g. Here, each of the lower gate lines 12g is provided so as to be electrically connected to a corresponding and overlapping one of the gate lines 16g to reduce the electrical resistance of the gate line 16g. As illustrated in FIG. 2, the TFT layer 30a also includes a plurality of source lines 18f provided as a plurality of third wiring lines so as to extend in parallel with each other in the Y-direction of the drawing so as to intersect with (orthogonal to) the plurality of gate lines 16g and the plurality of lower gate lines 12g. As illustrated in FIG. 2, the TFT layer 30a also includes a plurality of power supply lines 18g provided as a plurality of third wiring lines so as to extend in parallel with each other in the Y-direction of the drawing so as to intersect with (orthogonal to) the plurality of gate lines 16g and the plurality of lower gate lines 12g. Moreover, each of the power supply lines 18g is provided so as to be adjacent to a corresponding one of the source lines 18f, as illustrated in FIG. 2. Further, the TFT layer 30a includes, in each subpixel P, the first pixel TFT 9a, the second pixel TFT 9b, and the capacitor 9c, as illustrated in FIG. 4.

It is noted that the TFT layer 30a includes the following sequentially stacked on the resin substrate 10, as illustrated in FIG. 3: a base coat film 11; a first metal film, which constitutes a first gate electrode 12a and other components that will be described later on; a first gate insulating film 13 provided as a first inorganic insulating film; a semiconductor film, which constitutes a semiconductor layer 14a and other components that will be described later on; second gate insulating films 15a and 15ga (see FIGS. 6 and 7) provided as a third inorganic insulating film; a second metal film, which constitutes a second gate electrode 16a and other components that will be described later on; an interlayer insulating film 17 provided as a second inorganic insulating film; a third metal film, which constitutes the source lines 18f, power supply lines 18g, and other components; a protective insulating film 19; and a flattening film 20.

The base coat film 11, the first gate insulating film 13, the second gate insulating film 15a, the interlayer insulating film 17, and the protective insulating film 19 are formed from an inorganic insulating monolayer film or inorganic insulating multilayer film of, for instance, silicon nitride, silicon oxide, silicon oxide nitride, or other materials. Here, when the semiconductor layer 14a contains an oxide semiconductor, at least the first gate insulating film 13 and second gate insulating film 15a adjacent to the semiconductor layer 14a are formed from a silicon oxide film.

The lower gate lines 12g are formed in the first metal film. The gate lines 16g are formed in the second metal film. The source lines 18f and the power supply lines 18g are formed in the third metal film.

Here, in this embodiment, as illustrated in FIGS. 5, 6 and 7, a lower gate line 12ga is shown as a specific example of the lower gate lines 12g, and a gate line 16ga is shown as a specific example of the gate lines 16g. It is noted that between the lower gate line 12ga and the gate line 16ga, the first gate insulating film 13 and the second gate insulating film 15ga are stacked sequentially from the lower gate line 12ga toward the gate line 16ga, as illustrated in FIGS. 6 and 7.

As illustrated in FIG. 5, the lower gate line 12ga is provided so as to extend straight in the lateral direction of the drawing with a constant width.

As illustrated in FIG. 5, the gate line 16ga is provided so as to extend straight in the lateral direction of the drawing while alternately repeating a relatively wide portion, which is as wide as the lower gate line 12ga, and a relatively narrow portion.

As illustrated in FIG. 5, one end and the other end in the width direction of the lower gate line 12ga do not respectively partly overlap one end and the other end in the width direction of the gate line 16ga corresponding to one end and the other end of the lower gate line 12ga, because the gate line 16ga is narrower than the lower gate line 12ga in a part (i.e., on the right side of the drawing) between a pair of source line 18f and power supply line 18g adjacent to each other. Thus, between the pair of adjacent source line 18f and power supply line 18g, a film residue R of the third metal film may occur because, as illustrated in FIG. 6, the inclination of the side end of the interlayer insulating film 17 is relatively steep in the part in which one end and the other end in the width direction of the lower gate line 12ga overlap one end and the other end in the width direction of the gate line 16ga, whereas the film residue R of the third metal film can be less likely to occur because, as illustrated in FIG. 7, the inclination of the side end of the interlayer insulating film 17 is relatively gentle in the part in which one end and the other end in the width direction of the lower gate line 12ga do not overlap one end and the other end in the width direction of the gate line 16ga.

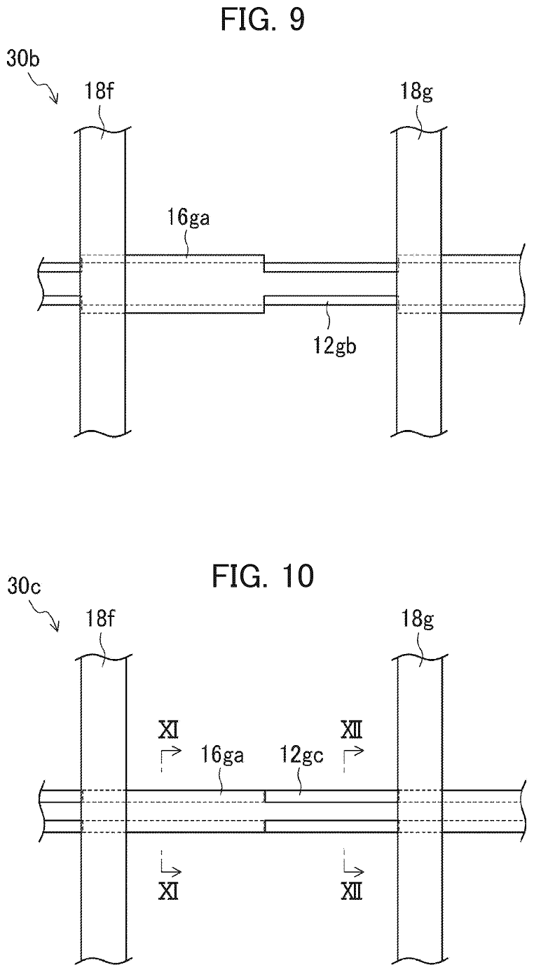

It is noted that although this embodiment has described, by way of example, a combination of gate lines in which the width of the lower gate line 12ga is set at the same width as the wide portion of the gate line 16ga, such a combination of gate lines as illustrated in FIG. 9 may be used. Here, FIG. 9 is a partial plan view of a TFT layer 30b, which is a modification of the TFT layer 30a, and corresponds to FIG. 5. Specifically in the TFT layer 30b, as illustrated in FIG. 9, the width (e.g., about 5 μm) of a lower gate line 12gb, which corresponds to the lower gate line 12ga, is set narrower than the width (e.g., about 7 μm) of the wide portion of the gate line 16ga in the other part (the left side of the drawing) between the pair of adjacent source line 18f and power supply line 18g. It is noted that in the TFT layer 30b, a gate line 16ga has a narrow portion having a width of, for instance, about 3 μm.

The first pixel TFT 9a in each subpixel P is electrically connected to the corresponding gate line 16g and source line 18f, as illustrated in FIG. 4. Further, the first pixel TFT 9a includes the following as illustrated in FIG. 3: the semiconductor layer 14a; the first gate electrode 12a provided under the semiconductor layer 14a in the drawing with the first gate insulating film 13 interposed therebetween; the second gate electrode 16a provided over the semiconductor layer 14a in the drawing with the second gate insulating film 15a interposed therebetween; and a source electrode 18a and a drain electrode 18b provided on the interlayer insulating film 17 so as to be spaced from each other.

The semiconductor layer 14a is formed from, for instance, a semiconductor film containing an oxide semiconductor, such as In—Ga—Zn—O, and includes, as illustrated in FIG. 3, a source region 14aa and a drain region 14ab defined so as to be spaced from each other, and a channel region 14ac defined between the source region 14aa and drain region 14ab. Here, an In—Ga—Zn—O semiconductor is a ternary oxide of indium (In), gallium (Ga), and zinc (Zn) and may contain In, Ga, and Zn at any ratio (composition ratio). Further, this In-Ga-Zn-O semiconductor may be amorphous or crystalline. It is noted that a preferable crystalline In-Ga-Zn-O semiconductor is a crystalline In—Ga—Zn—O semiconductor whose c-axis is nearly perpendicular to a layer surface. It is also noted that other kinds of oxide semiconductor may be contained instead of an In—Ga—Zn—O semiconductor. The other kinds of oxide semiconductor may include an In—Sn—Zn—O semiconductor (e.g., In₂O₃—SnO₂—ZnO, InSnZnO) for instance. Here, the In—Sn—Zn—O semiconductor is a ternary oxide of indium (In), tin (Sn), and zinc (Zn). Further, the other kinds of oxide semiconductor may include, but not limited to, an In—Al—Zn—O semiconductor, an In—Al—Sn—Zn—O semiconductor, a Zn—O semiconductor, an In—Zn—O semiconductor, a Zn—Ti—O semiconductor, a Cd—Ge—O semiconductor, a Cd—Pb—O semiconductor, a cadmium oxide (CdO), a Mg—Zn—O semiconductor, an In—Ga—Sn—O semiconductor, an In—Ga—O semiconductor, a Zr—In—Zn—O semiconductor, a Hf—In—Zn—O semiconductor, an Al—Ga—Zn—O semiconductor, a Ga—Zn—O semiconductor, an In—Ga—Zn—Sn—O semiconductor, InGaO₃ (ZnO)₅, magnesium zinc oxide (MgₓZn₁₋ₓO), and cadmium zinc oxide (CdₓZn₁₋ₓO). It is noted that a usable Zn—O semiconductor is an amorphous semiconductor of ZnO with one or more kinds of impurity elements selected from among, but not limited to, a Group I element, a Group XIII element, a Group XIV element, a Group XV element, and a Group XVII element being added thereto, a polycrystalline semiconductor of such ZnO, or a crystallite semiconductor of such ZnO including amorphous and polycrystalline substances; alternatively, a usable Zn—O semiconductor is a ZnO semiconductor without any impurity elements being added thereto.

The first gate electrode 12a is formed from the first metal film so as to overlap the channel region 14ac of the semiconductor layer 14a, as illustrated in FIG. 3, and is configured to control the electrical continuity between the source region 14aa and drain region 14ab of the semiconductor layer 14a. Here, the first gate electrode 12a and the second gate electrode 16a are electrically connected to each other.

The second gate electrode 16a is formed from the second metal film so as to overlap the channel region 14ac of the semiconductor layer 14a, as illustrated in FIG. 3, and is configured to control the electrical continuity between the source region 14aa and drain region 14ab of the semiconductor layer 14a.

The source electrode 18a and the drain electrode 18b are electrically connected to the source region 14aa and drain region 14ab of the semiconductor layer 14a, respectively, via respective contact holes Ha and Hb formed in the interlayer insulating film 17, as illustrated in FIG. 3. Here, the source electrode 18a and the drain electrode 18b are formed from the third metal film, like the source lines 18f and the power supply lines 18j.

The second pixel TFT 9b in each subpixel P is electrically connected to the corresponding first pixel TFT 9a and power supply line 18g, as illustrated in FIG. 4. Further, the second pixel TFT 9b includes, like the foregoing first pixel TFT 9a, the semiconductor layer 14a, the first gate electrode 12a, the second gate electrode 16a, the source electrode 18a, and the drain electrode 18b.

The capacitor 9c in each subpixel P is electrically connected to the corresponding first pixel TFT 9a and power supply line 18g, as illustrated in FIG. 4. Here, the capacitor 9c includes, for example, a lower conductive layer formed from the second metal film, an upper conductive layer formed from the third metal film, and the interlayer insulating film 17 provided between these lower conductive layer and upper conductive layer. It is noted that the upper conductive layer is electrically connected to the power supply line 18g via a contact hole formed in the interlayer insulating film 17.

The flattening film 20 has a flat surface in the display region D and contains, but not limited to, an organic resin material, such as polyimide resin.

As illustrated in FIG. 3, the organic EL element layer 40 includes a plurality of organic EL elements 35 provided as a plurality of light-emitting elements arranged on the TFT layer 30a in matrix in correspondence with the plurality of subpixels P. Here, the organic EL elements 35 each include the following as illustrated in FIG. 3: a first electrode 31 provided on the TFT layer 30a; the organic EL layer 33 provided on the first electrode 31; and a second electrode 34 provided on the organic EL layer 33 so as to be shared in the whole display region D.

The first electrode 31 is electrically connected to the drain electrode 18b of the second pixel TFT 9b in each subpixel P via a contact hole formed in the protective insulating film 19 and flattening film 20. Further, the first electrode 31 has the function of injecting holes (positive holes) into the organic EL layer 33. Further, the first electrode 31 is more desirably made of a material having a small work function in order to improve the efficiency of hole injection into the organic EL layer 33. Here, the first electrode 31 is made of, for instance, metal, such as silver (Ag), aluminum (Al), vanadium (V), cobalt (Co), nickel (Ni), tungsten (W), gold (Au), titanium (Ti), ruthenium (Ru), manganese (Mn), indium (In), ytterbium (Yb), lithium fluoride (LiF), platinum (Pt), palladium (Pd), molybdenum (Mo), iridium (Ir), and tin (Sn). Further, the first electrode 31 may be made of, for instance, alloy of astatine (At) and astatine oxide (AtO₂) or other alloys. Furthermore, the first electrode 31 may be made of, but not limited to, conductive oxide, including tin oxide (SnO), zinc oxide (ZnO), indium tin oxide (ITO), and indium zinc oxide (IZO). Further, the first electrode 31 may be formed by stacking multiple layers made of the above materials. It is noted that examples of a compound material having a large work function include indium tin oxide (ITO) and indium zinc oxide (IZO). Further, the first electrode 31 has a perimeter covered with an edge cover 32 provided all over the display region D in a lattice shape. Here, the edge cover 32 contains, but not limited to, an organic resin material, such as polyimide resin or acrylic resin, or a polysiloxane spin-on-glass (SOG) material.

As illustrated in FIG. 8, the organic EL layer 33 includes a hole injection layer 1, a hole transport layer 2, an emission layer 3, an electron transport layer 4, and an electron injection layer 5 sequentially stacked on the first electrode 31.

The hole injection layer 1 is also called an anode buffer layer, and has the function of bringing the energy levels of the first electrode 31 and organic EL layer 33 close to each other to improve the efficiency of hole injection from the first electrode 31 into the organic EL layer 33. Here, examples of the material of the hole injection layer 1 include a triazole derivative, an oxadiazole derivative, an imidazole derivative, a polyarylalkane derivative, a pyrazoline derivative, a phenylenediamine derivative, an oxazole derivative, a styrylanthracene derivative, a fluorenone derivative, a hydrazone derivative, and a stilbene derivative.

The hole transport layer 2 has the function of improving the efficiency of hole transport from the first electrode 31 to the organic EL layer 33. Here, examples of the material of the hole transport layer 2 include a porphyrin derivative, an aromatic tertiary amine compound, a styrylamine derivative, polyvinylcarbazole, poly-p-phenylenevinylene, polysilane, a triazole derivative, an oxadiazole derivative, an imidazole derivative, a polyarylalkane derivative, a pyrazoline derivative, a pyrazolone derivative, a phenylenediamine derivative, an arylamine derivative, an amine-substituted chalcone derivative, an oxazole derivative, a styrylanthracene derivative, a fluorenone derivative, a hydrazone derivative, a stilbene derivative, hydrogenated amorphous silicon, hydrogenated amorphous silicon carbide, zinc sulfide, and zinc selenide.

The emission layer 3 is a region in which holes and electrons are respectively injected from the first electrode 31 and second electrode 34 applied with voltage, and in which the holes and electrons recombine together. Here, the emission layer 3 contains a material having high efficiency of light emission. Moreover, examples of the material of the emission layer 3 include a metal oxinoid compound [8-hydroxyquinoline metal complex], a naphthalene derivative, an anthracene derivative, a diphenylethylene derivative, a vinyl acetone derivative, a triphenylamine derivative, a butadiene derivative, a coumarin derivative, a benzoxazole derivative, an oxadiazole derivative, an oxazole derivative, a benzimidazole derivative, a thiadiazole derivative, a benzothiazole derivative, a styryl derivative, a styrylamine derivative, a bisstyrylbenzene derivative, a trisstyrilbenzene derivative, a perylene derivative, a perynone derivative, an aminopyrene derivative, a pyridine derivative, a rhodamine derivative, an acridine derivative, phenoxazone, a quinacridone derivative, rubrene, poly-p-phenylenevinylene, and polysilane.

The electron transport layer 4 has the function of moving electrons to the emission layer 3 efficiently. Here, examples of the material of the electron transport layer 4 include organic compounds, such as an oxadiazole derivative, a triazole derivative, a benzoquinone derivative, a naphthoquinone derivative, an anthraquinone derivative, a tetracyanoanthraquinodimethane derivative, a diphenoquinone derivative, a fluorenone derivative, a silole derivative, and a metal oxinoid compound.

The electron injection layer 5 has the function of bringing the energy levels of the second electrode 34 and organic EL layer 33 close to each other to improve the efficiency of electron injection from the second electrode 34 into the organic EL layer 33. This function can lower voltage for driving the organic EL element 35. It is noted that the electron injection layer 5 is also called a cathode buffer layer. Here, examples of the material of the electron injection layer 5 include inorganic alkali compounds, such as lithium fluoride (LiF), magnesium fluoride (MgF₂), calcium fluoride (CaF2), strontium fluoride (SrF₂), or barium fluoride (BaF₂), as well as aluminum oxide (Al₂O₃) and strontium oxide (SrO).

The second electrode 34 is provided so as to cover the individual organic EL layer 33 and the edge cover 32, as illustrated in FIG. 3. Further, the second electrode 34 has the function of injecting electrons into the organic EL layer 33. Further, the second electrode 34 is more desirably made of a material having a small work function in order to improve the efficiency of electron injection into the organic EL layer 33. Here, examples of the material of the second electrode 34 include silver (Ag), aluminum (Al), vanadium (V), calcium (Ca), titanium (Ti), yttrium (Y), sodium (Na), manganese (Mn), indium (In), magnesium (Mg), lithium (Li), ytterbium (Yb), and lithium fluoride (LiF). Further, the second electrode 34 may contain, for instance, alloy of magnesium (Mg) and copper (Cu), alloy of magnesium (Mg) and silver (Ag), alloy of sodium (Na) and potassium (K), alloy of astatine (At) and astatine oxide (AtO₂), alloy of lithium (Li) and aluminum (Al), alloy of lithium (Li), calcium (Ca) and aluminum (Al), or alloy of lithium fluoride (LiF), calcium (Ca) and aluminum (Al). Further, the second electrode 34 may contain a conductive oxide, such as tin oxide (SnO), zinc oxide (ZnO), indium tin oxide (ITO), or indium zinc oxide (IZO). Further, the second electrode 34 may be formed by stacking multiple layers containing the above materials. It is noted that examples of the material having a small work function include magnesium (Mg), lithium (Li), lithium fluoride (LiF), magnesium (Mg)-copper (Cu), magnesium (Mg)-silver (Ag), sodium (Na)-potassium (K), lithium (Li)-aluminum (Al), lithium (Li)-calcium (Ca)-aluminum (Al), and lithium fluoride (LiF)-calcium (Ca)-aluminum (Al).

As illustrated in FIG. 3, the sealing film 45 is provided so as to cover the second electrode 34 and includes a first inorganic sealing film 41, an organic sealing film 42, and a second inorganic sealing film 43 sequentially stacked on the second electrode 34. The sealing film 45 has the function of protecting the organic EL layers 33 of the organic EL elements 35 from moisture, oxygen, and other things. Here, the first inorganic sealing film 41 and the second inorganic sealing film 43 are formed from an inorganic insulating film, such as a silicon nitride film, a silicon oxide film, or a silicon oxide nitride film. Further, the organic sealing film 42 contains an organic resin material, such as acrylic resin, epoxy resin, silicone resin, polyurea resin, parylene resin, polyimide resin, or polyamide resin.

The foregoing organic EL display device 50 is configured to display an image through the following process in each subpixel P: a gate signal is input to the first pixel TFT 9a via the gate line 16g to turn on the first pixel TFT 9a; a data signal is written into the first gate electrode 12a and second gate electrode 16a of the second pixel TFT 9b, and into the capacitor 9c via the source line 18f, and a current coming from the power supply line 18g and corresponding to the gate voltage of the second pixel TFT 9b is supplied to the organic EL layer 33, so that the emission layer 3 of the organic EL layer 33 emits light. It is noted that in the organic EL display device 50, the emission layer 3 continues to emit light until a gate signal in the next frame is input, because the capacitor 9c retains the gate voltage of the second pixel TFT 9b even when the first pixel TFT 9a is turned off.

Next, a method for manufacturing the organic EL display device 50 according to this embodiment will be described. Here, the method for manufacturing the organic EL display device 50 according to this embodiment includes a step of forming a TFT layer, a step of forming an organic EL element layer, and a step of forming a sealing film.

### Step of Forming TFT Layer

The first process step is forming the base coat film 11 by forming a silicon nitride film (about 50 nm thick) and a silicon oxide film (about 250 nm thick) sequentially onto the resin substrate 10 formed on a glass substrate through, for instance, plasma chemical vapor deposition (CVD).

The next is forming a first metal film, such as a molybdenum film (about 200 nm thick), onto the substrate surface with the base coat film 11 formed thereon, through, for instance, sputtering, followed by patterning the first metal film to form the first gate electrodes 12a, the lower gate lines 12g and other components.

The next is forming a silicon oxide film (about 100 nm thick) onto the substrate surface with the first gate electrodes 12a and other components formed thereon, through, for instance, plasma CVD to form the first gate insulating film 13.

The next is forming an oxide semiconductor film, such as an InGaZnO₄ film (about 30 nm thick), onto the substrate surface with the first gate insulating film 13 formed thereon, through, for instance, sputtering, followed by patterning the oxide semiconductor film to form the semiconductor layer 14a and other components.

The next is forming a silicon oxide film (about 100 nm thick) onto the substrate surface with the semiconductor layer 14a and other components formed thereon, through, for instance, plasma CVD, followed by forming a second metal film, such as a molybdenum film (about 200 nm thick), through sputtering, followed by patterning the second metal film to form the second gate electrodes 16a, the gate lines 16g, and other components.

The next is etching the silicon oxide film exposed from the second gate electrodes 16a, gate lines 16 and other components to form the second gate insulating films 15a and 15ga and other components.

The next is forming a silicon oxide film (about 300 nm thick) and a silicon nitride film (about 150 nm thick) sequentially onto the substrate surface with the second gate insulating films 15a and 15ga and other components formed thereon, through, for instance, plasma CVD to form the interlayer insulating film 17. It is noted that a part of the semiconductor layer 14a is turned into a conductor through heating after the formation of the interlayer insulating film 17, thus forming the source regions 14aa, drain regions 14ab, and channel regions 14ac in the semiconductor layer 14a.

The next is patterning the first gate insulating film 13 and the interlayer insulating film 17 appropriately on the substrate surface with the interlayer insulating film 17 formed thereon, to form contact holes.

The next is forming a titanium film (about 50 nm thick), an aluminum film (about 400 nm thick), and a titanium film (about 100 nm thick) sequentially onto the substrate surface with the contact holes formed therein, through, for instance, sputtering to form a third metal film, followed by patterning the third metal film through dry etching to form the source electrodes 18a, the drain electrodes 18b, the source lines 18f, the power supply lines 18g, and other components.

The next is forming a silicon oxide film (about 250 nm thick) onto the substrate surface with the source electrodes 18a and other components formed thereon, through, for instance, plasma CVD to form the protective insulating film 19.

The next is applying a photosensitive acrylic resin film (about 2 μm thick) onto the substrate surface with the protective insulating film 19 formed thereon, through, for instance, spin coating or slit coating, followed by subjecting the applied film to pre-baking, exposure, development, and post-baking to form the flattening film 20 having contact holes.

The final process step is removing the protective insulating film 21 exposed from the contact holes of the flattening film 20, to cause the contact holes to reach the drain electrodes 18b of the second pixel TFTs 9b.

The TFT layer 30a can be formed through the foregoing process steps.

### Step of Forming Organic EL Element Layer

The organic EL element layer 40 is formed by forming, through a well-known method, the first electrodes 31, the edge cover 32, the organic EL layers 33 (the hole injection layer 1, the hole transport layer 2, the emission layer 3, the electron transport layer 4, and the electron injection layer 5), and the second electrode 34 onto the flattening film 20 of the TFT layer 30a formed in the step of forming the TFT layer.

### Step of Forming Sealing Film

The first process step is forming an inorganic insulating film, such as a silicon nitride film, a silicon oxide film, or a silicon oxide nitride film, onto the substrate surface on which the organic EL element layer 40 formed in the step of forming the organic EL element layer is formed, through plasma CVD using a mask to form the first inorganic sealing film 41.

The next is forming a film of an organic resin material, such as acrylic resin, onto the substrate surface with the first inorganic sealing film 41 formed thereon, through, for instance, ink-jet printing to form the organic sealing film 42.

The next is forming an inorganic insulating film, such as a silicon nitride film, a silicon oxide film, or a silicon oxide nitride film, onto the substrate with the organic sealing film 42 formed thereon, through plasma CVD using a mask to form the second inorganic sealing film 43 to form the sealing film 45.

The final process step is attaching a protective sheet (not shown) to the substrate surface with the sealing film 45 formed thereon, followed by laser light irradiation from near the glass substrate of the resin substrate 10 to remove the glass substrate from the lower surface of the resin substrate 10, followed by attaching a protective sheet (not shown) to the lower surface of the resin substrate 10 with the glass substrate removed therefrom.

The organic EL display device 50 according to this embodiment can be manufactured through the foregoing process steps.

As described above, in the organic EL display device 50 including the TFT layer 30a according to this embodiment, between the pair of adjacent source line 18f and power supply line 18g, one end and the other end in the width direction of the lower gate line 12ga do not respectively partly overlap one end and the other end in the width direction of the gate line 16ga corresponding to one end and the other end of the lower gate line 12ga, because the gate line 16ga is narrower than the lower gate line 12ga in a part between the pair of adjacent source line 18f and power supply line 18g. Thus, between the pair of adjacent source line 18f and power supply line 18g, the inclination of the side end of the interlayer insulating film 17 is relatively steep in the part in which one end and the other end in the width direction of the lower gate line 12ga overlap one end and the other end in the width direction of the gate line 16ga, whereas the inclination of the side end of the interlayer insulating film 17 is relatively gentle in the part in which one end and the other end in the width direction of the lower gate line 12ga do not overlap one end and the other end in the width direction of the gate line 16ga. Thus, when the third metal film, which is formed so as to cover the interlayer insulating film 17, undergoes patterning through dry etching, the film residue R may occur in the location in which the inclination of the side end of the interlayer insulating film 17 is relatively steep, whereas the film residue R is less likely to occur in the location in which the inclination of the side end of the interlayer insulating film 17 is relatively gentle. As a result, between the pair of adjacent source line 18f and power supply line 18g, the film residue R of the third metal film is less likely to be continuously formed in the direction in which the lower gate line 12ga and the gate line 16ga extend, so that a short circuit can be prevented between the pair of adjacent source line 18f and power supply line 18g. This can prevent a short circuit between the pair of adjacent source line 18f and power supply line 18g orthogonal to the lower gate line 12ga and gate line 16ga, on the interlayer insulating film 17 covering the gate line 16ga overlapping the lower gate line 12ga. It is noted that although this embodiment has described, by way of example, a wiring configuration that can prevent a short circuit between the pair of adjacent source line 18f and power supply line 18g, a short circuit can be prevented between a pair of adjacent source lines 18f when, for instance, the power supply lines 18g are formed in a layer (e.g., a layer between the protective insulating film 19 and flattening film 20) that is different from the layer including the source lines 18f.

### Second Embodiment

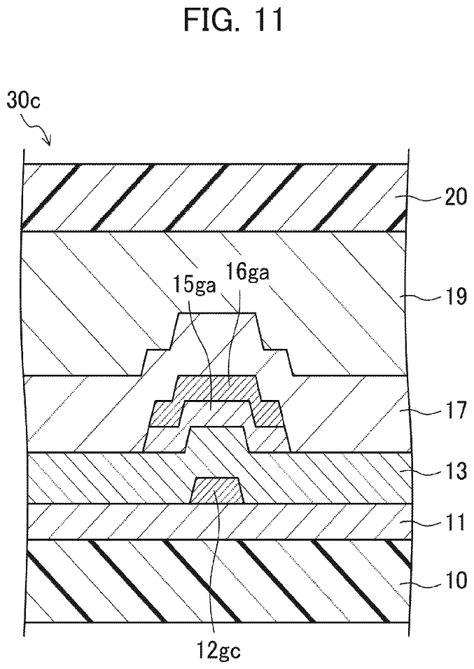

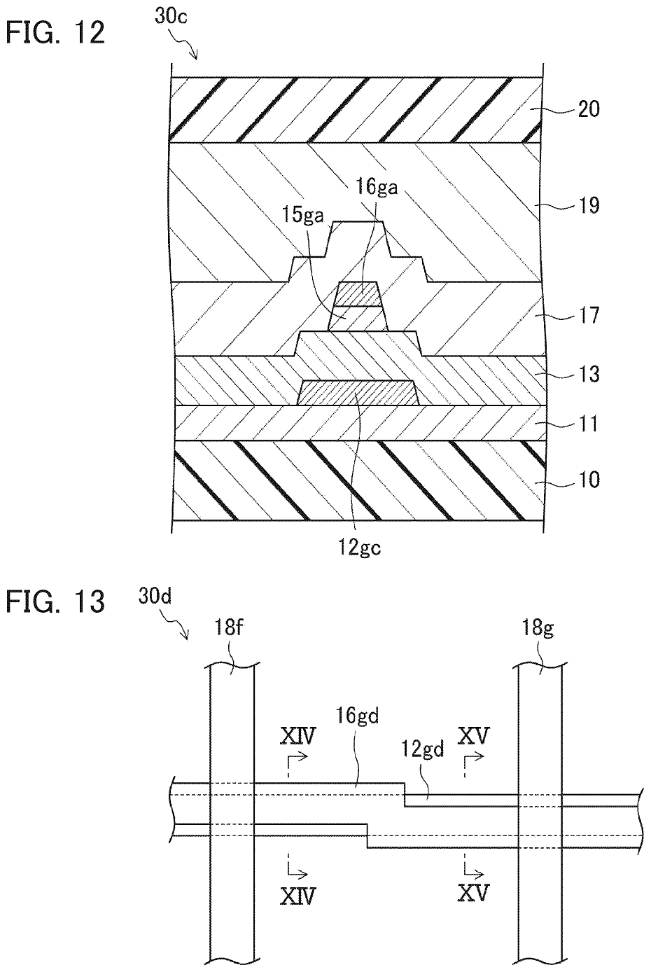

FIGS. 10 to 12 illustrate a display device according to a second embodiment of the disclosure. Here, FIG. 10 is a partial plan view of a TFT layer 30c constituting an organic EL display device according to this embodiment, and corresponds to FIG. 5 described in the first embodiment. In addition, FIGS. 11 and 12 are cross-sectional views of the TFT layer 30c taken along lines XI-XI and XII-XII in FIG. 10. It is noted that the same components as those illustrated in FIGS. 1 to 9 will be denoted by the same signs in the following embodiment, and their detailed descriptions will be omitted.

The first embodiment has described, by way of example, the organic EL display device 50 including the TFT layer 30a(30b ) in which the gate line 16ga is provided partly narrow in a part between the pair of adjacent source line 18f and power supply line 18g. This embodiment describes, by way of example, an organic EL display device including the TFT layer 30c in which a lower gate line 12gc and the gate line 16ga are provided partly narrow in a part between the pair of adjacent source line 18f and power supply line 18g.

Like the organic EL display device 50 according to the first embodiment, the organic EL display device according to this embodiment includes the display device D for image display, and the frame region F provided around the display region D. The organic EL display device according to this embodiment also includes the following: the resin substrate 10 provided as a base substrate; the TFT layer 30c provided on the resin substrate 10; the organic EL element layer 40 provided as a light-emitting element layer on the TFT layer 30c; and the sealing film 45 provided on the organic EL element layer 40.

Like the TFT layer 30a according to the first embodiment, the TFT layer 30c includes the following: the base coat film 11 provided on the resin substrate 10; a plurality of first pixel TFTs 9a, a plurality of second pixel TFTs 9b, and a plurality of capacitors 9c provided on the base coat film 11; and the protective insulating film 19 and the flattening film 20 provided sequentially on the first pixel TFTs 9a, second pixel TFTs 9b, and capacitors 9c.

Like the TFT layer 30a according to the first embodiment, the TFT layer 30c includes a plurality of gate lines 16g (16ga) as a plurality of second wiring lines, and a plurality of lower gate lines 12g (12gc) as a plurality of first wiring lines. Like the TFT layer 30a according to the first embodiment, the TFT layer 30c also includes a plurality of source lines 18f and a plurality of power supply lines 18g as a plurality of third wiring lines. Like the TFT layer 30a according to the first embodiment, the TFT layer 30c also includes, in each subpixel P, the first pixel TFT 9a, the second pixel TFT 9b, and the capacitor 9c. Like the TFT layer 30a according to the first embodiment, the TFT layer 30c also includes the following sequentially stacked on the resin substrate 10: the base coat film 11; a first metal film, which constitutes the first gate electrode 12a and other components; the first gate insulating film 13 provided as a first inorganic insulating film; a semiconductor film, which constitutes the semiconductor layer 14a and other components; the second gate insulating films 15a and 15ga provided as a third inorganic insulating film; a second metal film, which constitutes the second gate electrode 16a and other components; the interlayer insulating film 17 provided as a second inorganic insulating film; a third metal film, which constitutes the source lines 18f, power supply lines 18g, and other components; the protective insulating film 19; and the flattening film 20.

Here, in this embodiment, as illustrated in FIGS. 10, 11 and 12, the lower gate line 12gc is shown as a specific example of the lower gate lines 12g, and the gate line 16ga is shown as a specific example of the gate lines 16g. It is noted that between the lower gate line 12gc and the gate line 16ga, the first gate insulating film 13 and the second gate insulating film 15ga are stacked sequentially from the lower gate line 12gc toward the gate line 16ga, as illustrated in FIGS. 11 and 12.

As illustrated in FIG. 10, one end and the other end in the width direction of the lower gate line 12gc do not respectively partly overlap one end and the other end in the width direction of the gate line 16ga corresponding to one end and the other end of the lower gate line 12gc, because the gate line 16ga is narrower than the lower gate line 12ga in a part (i.e., on the right side of the drawing) between the pair of adjacent source line 18f and power supply line 18g, and because the gate line 16ga is wider than the lower gate line 12gc in the other part (i.e., on the left side of the drawing) between the pair of adjacent source line 18f and power supply line 18g. Here, as illustrated in FIG. 10, the lower gate line 12gc is provided relatively wide in a part (i.e., on the right side of the drawing) between the pair of adjacent source line 18f and power supply line 18g, and relatively narrow in the other part (i.e., on the left side of the drawing) between the pair of adjacent source line 18f and power supply line 18g. Further, as illustrated in FIG. 10, the gate line 16ga is provided relatively narrow in the part (i.e., on the right side of the drawing) between the pair of adjacent source line 18f and power supply line 18g, and relatively wide in the other part (i.e., on the left side of the drawing) between the pair of adjacent source line 18f and power supply line 18g. Accordingly, the portion in which one end and the other end in the width direction of the lower gate line 12gc do not overlap one end and the other end in the width direction of the gate line 16ga mostly occupies between the pair of adjacent source line 18f and power supply line 18g; in this non-overlapping portion, the inclination of the side end of the interlayer insulating film 17 is gentle, as illustrated in FIGS. 11 and 12, so that the film residue R of the third metal film can be less likely to occur.

Like the organic EL display device 50 according to the first embodiment, the organic EL display device including the TFT layer 30c with the foregoing configuration is configured such that the organic EL element 35 in each subpixel P emits light at a luminance level corresponding to a driving current, to display an image.

The organic EL display device including the TFT layer 30c according to this embodiment can be manufactured by changing the pattern shapes of the first and second metal films in the step of forming the TFT layer of the method for manufacturing the organic EL display device 50 according to the first embodiment.

As described above, in the organic EL display device including the TFT layer 30c according to this embodiment, between the pair of adjacent source line 18f and power supply line 18g, one end and the other end in the width direction of the lower gate line 12gc do not respectively partly overlap one end and the other end in the width direction of the gate line 16ga corresponding to one end and the other end of the lower gate line 12gc, because the gate line 16ga is narrower than the lower gate line 12gc in a part between the pair of adjacent source line 18f and power supply line 18g and is wider than the lower gate line 12gc in the other part between the pair of adjacent source line 18f and power supply line 18g. Accordingly, the portion in which one end and the other end in the width direction of the lower gate line 12gc do not overlap one end and the other end in the width direction of the gate line 16ga mostly occupies between the pair of adjacent source line 18f and power supply line 18g; in this non-overlapping portion, the inclination of the side end of the interlayer insulating film 17 is gentle, so that the film residue R of the third metal film is less likely to occur. As a result, between the pair of adjacent source line 18f and power supply line 18g, the film residue R of the third metal film is less likely to be continuously formed in the direction in which the lower gate line 12gc and the gate line 16ga extend, so that a short circuit can be prevented between the pair of adjacent source line 18f and power supply line 18g. This can prevent a short circuit between the pair of adjacent source line 18f and power supply line 18g orthogonal to the lower gate line 12gc and gate line 16ga, on the interlayer insulating film 17 covering the gate line 16ga overlapping the lower gate line 12gc. It is noted that although this embodiment has described, by way of example, a wiring configuration that can prevent a short circuit between the pair of adjacent source line 18f and power supply line 18g, a short circuit can be prevented between the pair of adjacent source lines 18f when, for instance, the power supply lines 18g are formed in a layer (e.g., a layer between the protective insulating film 19 and flattening film 20) that is different from the layer including the source lines 18f.

### Third Embodiment

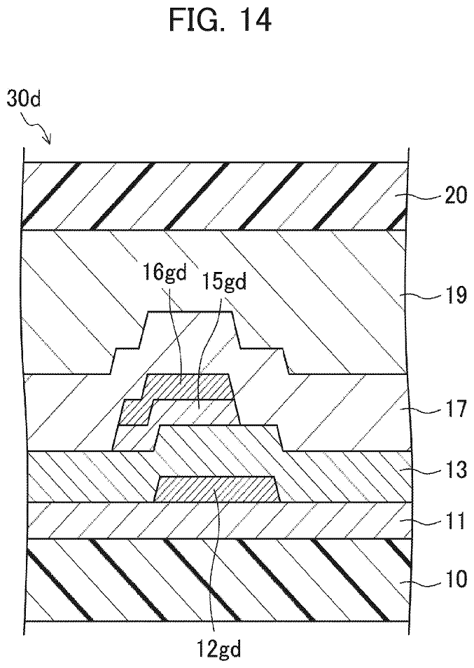

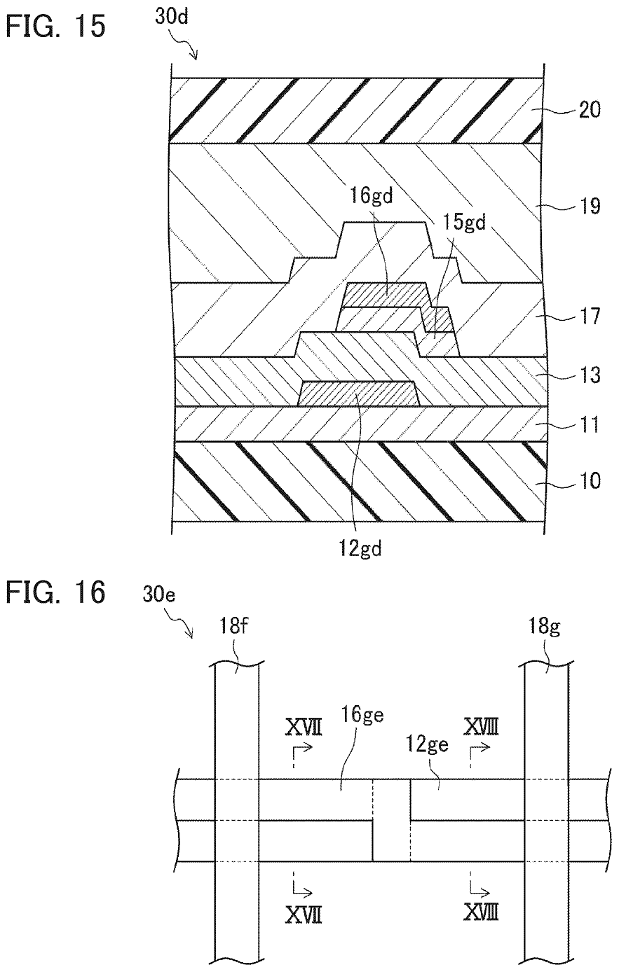

FIGS. 13 to 15 illustrate a display device according to a third embodiment of the disclosure. Here, FIG. 13 is a partial plan view of a TFT layer 30d constituting an organic EL display device according to this embodiment, and corresponds to FIG. 5 described in the first embodiment. In addition, FIGS. 14 and 15 are cross-sectional views of the TFT layer taken along lines XIV-XIV and XV-XV in FIG. 13.

The first (or second) embodiment has described, by way of example, the organic EL display device 50 including the TFT layer 30a (or 30c) in which the lower gate line 12ga (or 12gc) and the gate line 16ga are provided so as to extend straight. This embodiment describes the organic EL display device including the TFT layer 30d in which a gate line 16gd is provided so as to flex once in the middle in a part between the pair of adjacent source line 18f and power supply line 18g.

Like the organic EL display device 50 according to the first embodiment, the organic EL display device according to this embodiment includes the display device D for image display, and the frame region F provided around the display region D. The organic EL display device according to this embodiment also includes the following: the resin substrate 10 provided as a base substrate; the TFT layer 30d provided on the resin substrate 10; the organic EL element layer 40 provided as a light-emitting element layer on the TFT layer 30d; and the sealing film 45 provided on the organic EL element layer 40.

Like the TFT layer 30a according to the first embodiment, the TFT layer 30d includes the following: the base coat film 11 provided on the resin substrate 10; a plurality of first pixel TFTs 9a, a plurality of second pixel TFTs 9b, and a plurality of capacitors 9c provided on the base coat film 11; and the protective insulating film 19 and the flattening film 20 provided sequentially on the first pixel TFTs 9a, second pixel TFTs 9b, and capacitors 9c.

Like the TFT layer 30a according to the first embodiment, the TFT layer 30d includes a plurality of gate lines 16g (16gd) as a plurality of second wiring lines, and a plurality of lower gate lines 12g (12gd) as a plurality of first wiring lines. Like the TFT layer 30a according to the first embodiment, the TFT layer 30d also includes a plurality of source lines 18f and a plurality of power supply lines 18g as a plurality of third wiring lines. Like the TFT layer 30a according to the first embodiment, the TFT layer 30d also includes, in each subpixel P, the first pixel TFT 9a, the second pixel TFT 9b, and the capacitor 9c. Like the TFT layer 30a according to the first embodiment, the TFT layer 30d also includes the following sequentially stacked on the resin substrate 10: the base coat film 11; a first metal film, which constitutes the first gate electrode 12a and other components; the first gate insulating film 13 provided as a first inorganic insulating film; a semiconductor film, which constitutes the semiconductor layer 14a and other components; the second gate insulating film 15a and a second gate insulating film 15gd (see FIGS. 14 and 15) provided as a third inorganic insulating film; a second metal film, which constitutes the second gate electrode 16a and other components; the interlayer insulating film 17 provided as a second inorganic insulating film; a third metal film, which constitutes the source lines 18f, power supply lines 18g, and other components; the protective insulating film 19; and the flattening film 20.

Here, in this embodiment, as illustrated in FIGS. 13, 14 and 15, the lower gate line 12gd is shown as a specific example of the lower gate lines 12g, and the gate line 16gd is shown as a specific example of the gate lines 16g. It is noted that between the lower gate line 12gd and the gate line 16gd, the first gate insulating film 13 and the second gate insulating film 15gd are stacked sequentially from the lower gate line 12gd toward the gate line 16gd, as illustrated in FIGS. 14 and 15.

As illustrated in FIG. 13, the lower gate line 12gd is provided so as to extend straight in the lateral direction of the drawing with a constant width.

As illustrated in FIG. 13, the gate line 16gd is provided between the pair of adjacent source line 18f and power supply line 18g so as to extend in the lateral direction of the drawing from one end to the middle, then flex once in the longitudinal direction of the drawing in the middle, and then extend in the lateral direction of the drawing from the middle to the other end.

As illustrated in FIG. 13, one end and the other end in the width direction of the lower gate line 12gd do not respectively partly overlap one end and the other end in the width direction of the gate line 16gd corresponding to one end and the other end of the lower gate line 12gd, because the gate line 16gd is provided so as to flex once in the longitudinal direction of the drawing in the middle between the pair of adjacent source line 18f and power supply line 18g, and because the gate line 16gd protruding from the lower gate line 12gd in plan view changes its protrusion direction in the middle. Accordingly, the portion in which one end and the other end in the width direction of the lower gate line 12gd do not overlap one end and the other end in the width direction of the gate line 16gd mostly occupies between the pair of adjacent source line 18f and power supply line 18g; in this non-overlapping portion, the inclination of the side end of the interlayer insulating film 17 is gentle, as illustrated in FIGS. 14 and 15, so that the film residue R of the third metal film can be less likely to occur.

It is noted that although this embodiment has described, by way of example, the TFT layer 30d in which the lower gate line 12gd extends straight, and in which the gate line 16gd flexes once, the TFT layer 30d may be conversely configured such that the gate line 16gd extends straight, such that the lower gate line 12gd flexes once, and such that the lower gate line 12gd protruding from the gate line 16gd in plan view changes its protrusion direction in the middle between the pair of adjacent source line 18f and power supply line 18g.

Like the organic EL display device 50 according to the first embodiment, the organic EL display device including the TFT layer 30d with the foregoing configuration is configured such that the organic EL element 35 in each subpixel P emits light at a luminance level corresponding to a driving current, to display an image.

The organic EL display device including the TFT layer 30d according to this embodiment can be manufactured by changing the pattern shapes of the first and second metal films in the step of forming the TFT layer of the method for manufacturing the organic EL display device 50 according to the first embodiment.

As described above, in the organic EL display device including the TFT layer 30d according to this embodiment, one end and the other end in the width direction of the lower gate line 12gd do not respectively partly overlap one end and the other end in the width direction of the gate line 16gd corresponding to one end and the other end of the lower gate line 12gd, because the gate line 16gd is provided so as to flex once in the middle between the pair of adjacent source line 18f and power supply line 18g, and because the gate line 16gd protruding from the lower gate line 12gd in plan view changes its protrusion direction in the middle. Accordingly, the portion in which one end and the other end in the width direction of the lower gate line 12gd do not overlap one end and the other end in the width direction of the gate line 16gd mostly occupies between the pair of adjacent source line 18f and power supply line 18g; in this non-overlapping portion, the inclination of the side end of the interlayer insulating film 17 is gentle, so that the film residue R of the third metal film is less likely to occur. As a result, between the pair of adjacent source line 18f and power supply line 18g, the film residue R of the third metal film is less likely to be continuously formed in the direction in which the lower gate line 12gd and the gate line 16gd extend, so that a short circuit can be prevented between the pair of adjacent source line 18f and power supply line 18g. This can prevent a short circuit between the pair of adjacent source line 18f and power supply line 18g orthogonal to the lower gate line 12gd and gate line 16gd, on the interlayer insulating film 17 covering the gate line 16gd overlapping the lower gate line 12gd. It is noted that although this embodiment has described, by way of example, a wiring configuration that can prevent a short circuit between the pair of adjacent source line 18f and power supply line 18g, a short circuit can be prevented between the pair of adjacent source lines 18f when, for instance, the power supply lines 18g are formed in a layer (e.g., a layer between the protective insulating film 19 and flattening film 20) that is different from the layer including the source lines 18f.

### Fourth Embodiment

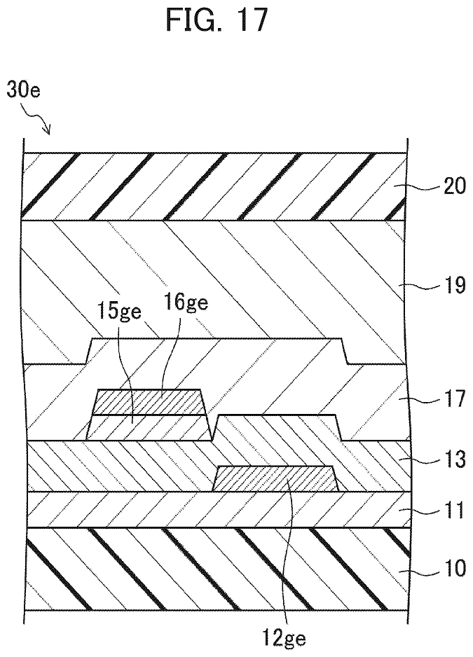

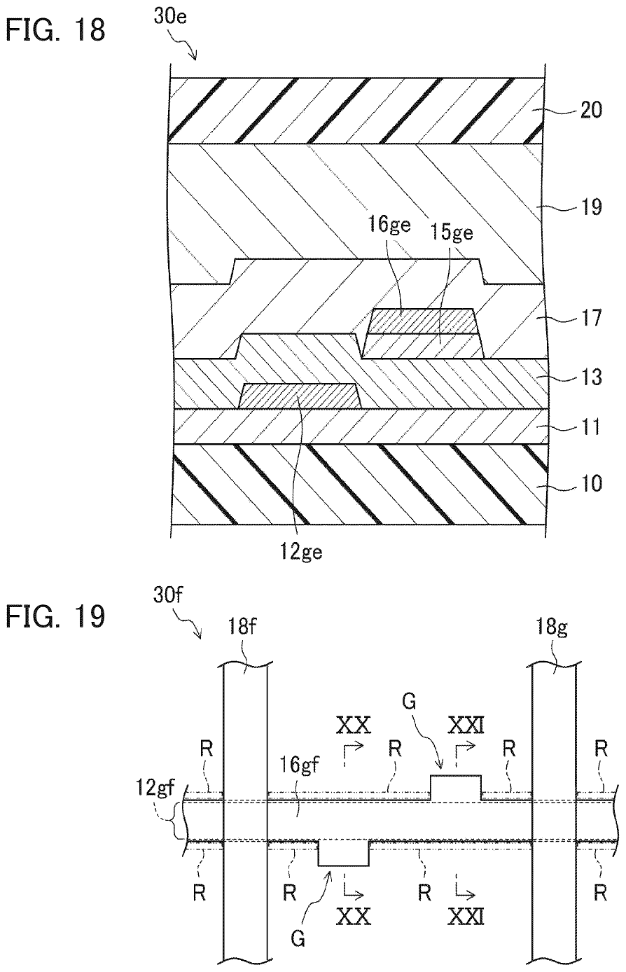

FIGS. 16 to 18 illustrate a display device according to a fourth embodiment of the disclosure. Here, FIG. 16 is a partial plan view of a TFT layer 30e constituting an organic EL display device according to this embodiment, and corresponds to FIG. 5 described in the first embodiment. In addition, FIGS. 17 and 18 are cross-sectional views of the TFT layer 30e taken along lines XVII-XVII and XVIII-XVIII in FIG. 16.

The third embodiment has described, by way of example, the organic EL display device including the TFT layer 30d in which the gate line 16gd is provided so as to flex once in its middle in a part between the pair of adjacent source line 18f and power supply line 18g. This embodiment describes the organic EL display device including the TFT layer 30e in which a lower gate line 12ge and a gate line 16ge are provided so as to flex once in their middles.

Like the organic EL display device 50 according to the first embodiment, the organic EL display device according to this embodiment includes the display device D for image display, and the frame region F provided around the display region D. The organic EL display device according to this embodiment also includes the following: the resin substrate 10 provided as a base substrate; the TFT layer 30e provided on the resin substrate 10; the organic EL element layer 40 provided as a light-emitting element layer on the TFT layer 30e; and the sealing film 45 provided on the organic EL element layer 40.

Like the TFT layer 30a according to the first embodiment, the TFT layer 30e includes the following: the base coat film 11 provided on the resin substrate 10; a plurality of first pixel TFTs 9a, a plurality of second pixel TFTs 9b, and a plurality of capacitors 9c provided on the base coat film 11; and the protective insulating film 19 and the flattening film 20 provided sequentially on the first pixel TFTs 9a, second pixel TFTs 9b, and capacitors 9c.

Like the TFT layer 30a according to the first embodiment, the TFT layer 30e includes a plurality of gate lines 16g (16ge) as a plurality of second wiring lines, and a plurality of lower gate lines 12g (12ge) as a plurality of first wiring lines. Like the TFT layer 30a according to the first embodiment, the TFT layer 30e also includes a plurality of source lines 18f and a plurality of power supply lines 18g as a plurality of third wiring lines. Like the TFT layer 30a according to the first embodiment, the TFT layer 30e also includes, in each subpixel P, the first pixel TFT 9a, the second pixel TFT 9b, and the capacitor 9c. Like the TFT layer 30a according to the first embodiment, the TFT layer 30e also includes the following sequentially stacked on the resin substrate 10: the base coat film 11; a first metal film, which constitutes the first gate electrode 12a and other components; the first gate insulating film 13 provided as a first inorganic insulating film; a semiconductor film, which constitutes the semiconductor layer 14a and other components; the second gate insulating film 15a and a second gate insulating film 15ge (see FIGS. 17 and 18) provided as a third inorganic insulating film; a second metal film, which constitutes the second gate electrode 16a and other components; the interlayer insulating film 17 provided as a second inorganic insulating film; a third metal film, which constitutes the source lines 18f, power supply lines 18g, and other components; the protective insulating film 19; and the flattening film 20.

Here, in this embodiment, as illustrated in FIGS. 16, 17 and 18, the lower gate line 12ge is shown as a specific example of the lower gate lines 12g, and the gate line 16ge is shown as a specific example of the gate lines 16g. It is noted that between the lower gate line 12ge and the gate line 16ge, the first gate insulating film 13 and the second gate insulating film 15ge are stacked sequentially from the lower gate line 12ge toward the gate line 16ge, as illustrated in FIGS. 17 and 18.

As illustrated in FIG. 16, the lower gate line 12ge is provided between the pair of adjacent source line 18f and power supply line 18g so as to extend in the lateral direction of the drawing from one end to the middle, then flex once in the longitudinal direction of the drawing in the middle, and then extend in the lateral direction of the drawing from the middle to the other end.

As illustrated in FIG. 16, the gate line 16ge is provided between the pair of adjacent source line 18f and power supply line 18g so as to extend in the lateral direction of the drawing from one end to the middle, then flex once in the longitudinal direction of the drawing in the middle, and then extend in the lateral direction of the drawing from the middle to the other end. Here, in a portion in which the lower gate line 12ge and the gate line 16ge overlap each other, the lower gate line 12ge flexes to the upper side of the drawing, and the gate line 16ge flexes to the lower side of the drawing, as illustrated in FIG. 16, when they are viewed from one side (the left side of the drawing) to the other side (the right side of the drawing) in their length direction; thus, these lines flex in mutually 180-degree different directions.

As illustrated in FIG. 16, one end and the other end in the width direction of the lower gate line 12ge do not respectively partly overlap one end and the other end in the width direction of the gate line 16ge corresponding to one end and the other end of the lower gate line 12ge, because the lower gate line 12ge and the gate line 16ge are provided so as to flex once in the longitudinal direction of the drawing in the middle between the pair of adjacent source line 18f and power supply line 18g, and because the lower gate line 12ge and the gate line 16ge flex in mutually different directions in the overlapping portion between them. Accordingly, the portion in which one end and the other end in the width direction of the lower gate line 12ge do not overlap one end and the other end in the width direction of the gate line 16ge mostly occupies between the pair of adjacent source line 18f and power supply line 18g; in this non-overlapping portion, the inclination of the side end of the interlayer insulating film 17 is gentle, as illustrated in FIGS. 17 and 18, so that the film residue R of the third metal film can be less likely to occur.

Like the organic EL display device 50 according to the first embodiment, the organic EL display device including the TFT layer 30e with the foregoing configuration is configured such that the organic EL element 35 in each subpixel P emits light at a luminance level corresponding to a driving current, to display an image.

The organic EL display device including the TFT layer 30e according to this embodiment can be manufactured by changing the pattern shapes of the first and second metal films in the step of forming the TFT layer of the method for manufacturing the organic EL display device 50 according to the first embodiment.

As described above, in the organic EL display device including the TFT layer 30e according to this embodiment, between the pair of adjacent source line 18f and power supply line 18g, one end and the other end in the width direction of the lower gate line 12ge do not respectively partly overlap one end and the other end in the width direction of the gate line 16ge corresponding to one end and the other end of the lower gate line 12ge, because the lower gate line 12ge and the gate line 16ge are provided so as to flex once in the middle between the pair of adjacent source line 18f and power supply line 18g, and because the lower gate line 12ge and the gate line 16ge flex in mutually different directions in the overlapping portion between them. Accordingly, the portion in which one end and the other end in the width direction of the lower gate line 12ge do not overlap one end and the other end in the width direction of the gate line 16ge mostly occupies between the pair of adjacent source line 18f and power supply line 18g; in this non-overlapping portion, the inclination of the side end of the interlayer insulating film 17 is gentle, so that the film residue R of the third metal film is less likely to occur. As a result, between the pair of adjacent source line 18f and power supply line 18g, the film residue R of the third metal film is less likely to be continuously formed in the direction in which the lower gate line 12ge and the gate line 16ge extend, so that a short circuit can be prevented between the pair of adjacent source line 18f and power supply line 18g. This can prevent a short circuit between the pair of adjacent source line 18f and power supply line 18g orthogonal to the lower gate line 12ge and gate line 16ge, on the interlayer insulating film 17 covering the gate line 16ge overlapping the lower gate line 12ge. It is noted that although this embodiment has described, by way of example, a wiring configuration that can prevent a short circuit between the pair of adjacent source line 18f and power supply line 18g, a short circuit can be prevented between the pair of adjacent source lines 18f when, for instance, the power supply lines 18g are formed in a layer (e.g., a layer between the protective insulating film 19 and flattening film 20) that is different from the layer including the source lines 18f.

### Fifth Embodiment

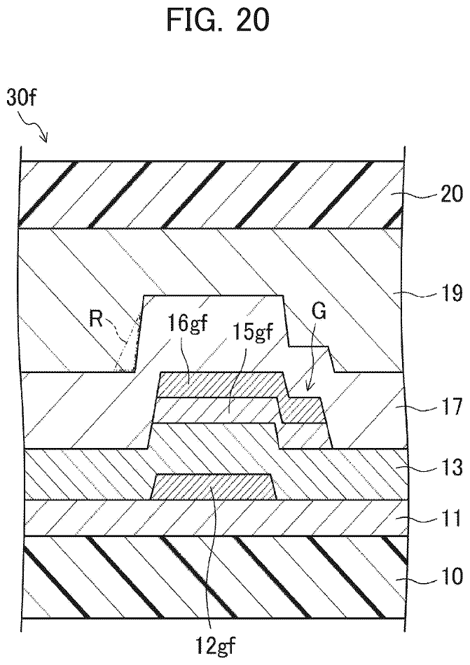

FIGS. 19 to 21 illustrate a display device according to a fifth embodiment of the disclosure. Here, FIG. 19 is a partial plan view of a TFT layer 30f constituting an organic EL display device according to this embodiment, and corresponds to FIG. 5 described in the first embodiment. In addition, FIGS. 20 and 21 are cross-sectional views of the TFT layer taken along lines XX-XX and XXI-XXI in FIG. 19.

The foregoing embodiments have each described, by way of example, an organic EL display device including a TFT layer in which the lower gate lines 12g and the gate lines 16g are provided so as not to protrude sideward locally. This embodiment describes, by way of example, the organic EL display device including the TFT layer 30f in which a gate line 16gf is provided so as to protrude sideward locally.

Like the organic EL display device 50 according to the first embodiment, the organic EL display device according to this embodiment includes the display device D for image display, and the frame region F provided around the display region D. The organic EL display device according to this embodiment also includes the following: the resin substrate 10 provided as a base substrate; the TFT layer 30f provided on the resin substrate 10; the organic EL element layer 40 provided as a light-emitting element layer on the TFT layer 30f; and the sealing film 45 provided on the organic EL element layer 40.

Like the TFT layer 30a according to the first embodiment, the TFT layer 30f includes the following: the base coat film 11 provided on the resin substrate 10; a plurality of first pixel TFTs 9a, a plurality of second pixel TFTs 9b, and a plurality of capacitors 9c provided on the base coat film 11; and the protective insulating film 19 and the flattening film 20 provided sequentially on the first pixel TFTs 9a, second pixel TFTs 9b, and capacitors 9c.

Like the TFT layer 30a according to the first embodiment, the TFT layer 30f includes a plurality of gate lines 16g (16gf) as a plurality of second wiring lines, and a plurality of lower gate lines 12g (12gf) as a plurality of first wiring lines. Like the TFT layer 30a according to the first embodiment, the TFT layer 30f also includes a plurality of source lines 18f and a plurality of power supply lines 18g as a plurality of third wiring lines. Like the TFT layer 30a according to the first embodiment, the TFT layer 30f also includes, in each subpixel P, the first pixel TFT 9a, the second pixel TFT 9b, and the capacitor 9c. Like the TFT layer 30a according to the first embodiment, the TFT layer 30f also includes the following sequentially stacked on the resin substrate 10: the base coat film 11; a first metal film, which constitutes the first gate electrode 12a and other components; the first gate insulating film 13 provided as a first inorganic insulating film; a semiconductor film, which constitutes the semiconductor layer 14a and other components; the second gate insulating film 15a and a second gate insulating film 15gf (see FIGS. 20 and 21) provided as a third inorganic insulating film; a second metal film, which constitutes the second gate electrode 16a and other components; the interlayer insulating film 17 provided as a second inorganic insulating film; a third metal film, which constitutes the source lines 18f, power supply lines 18g, and other components; the protective insulating film 19; and the flattening film 20.

Here, in this embodiment, as illustrated in FIGS. 19, 20 and 21, the lower gate line 12gf is shown as a specific example of the lower gate lines 12g, and the gate line 16gf is shown as a specific example of the gate lines 16g. It is noted that between the lower gate line 12gf and the gate line 16gf, the first gate insulating film 13 and the second gate insulating film 15gf are stacked sequentially from the lower gate line 12gf toward the gate line 16gf, as illustrated in FIGS. 20 and 21.

As illustrated in FIG. 19, the lower gate line 12gf is provided so as to extend straight in the lateral direction of the drawing with a constant width.

As illustrated in FIG. 19, the gate line 16gf includes, between the pair of adjacent source line 18f and power supply line 18g, a protrusion G provided at one end in its width direction and protruding in the width direction, and a protrusion G providing at the other end in its width direction and protruding in the width direction.

As illustrated in FIG. 19, between the pair of adjacent source line 18f and power supply line 18g, one end and the other end in the width direction of the lower gate line 12gf do not respectively partly overlap one end and the other end in the width direction of the gate line 16gf corresponding to one end and the other end of the lower gate line 12gf, because the protrusion G protruding toward the upper side of the drawing is provided at one end (i.e., the upper end of the drawing) in the width direction of the gate line 16gf, and the protrusion G protruding toward the lower side of the drawing is provided at the other end (i.e., the lower end of the drawing) in the width direction of the gate line 16gf. Thus, between the pair of adjacent source line 18f and power supply line 18g, the film residue R of the third metal film may occur in the part in which one end and the other end in the width direction of the lower gate line 12gf overlap one end and the other end in the width direction of the gate line 16gf because, as illustrated in FIGS. 20 and 21, the inclination of the side end of the interlayer insulating film 17 is relatively steep, whereas the film residue R of the third metal film can be less likely to occur in the part in which one end and the other end in the width direction of the lower gate line 12gf do not overlap one end and the other end in the width direction of the gate line 16gf because, as illustrated in FIGS. 20 and 21, the inclination of the side end of the interlayer insulating film 17 is relatively gentle.

It is noted that although this embodiment has described, by way of example, the TFT layer 30f including the protrusions G in the gate line 16gf, the protrusions G may be provided in the lower gate line 12gf.

Like the organic EL display device 50 according to the first embodiment, the organic EL display device including the TFT layer 30f with the foregoing configuration is configured such that the organic EL element 35 in each subpixel P emits light at a luminance level corresponding to a driving current, to display an image.

The organic EL display device including the TFT layer 30f according to this embodiment can be manufactured by changing the pattern shapes of the first and second metal films in the step of forming the TFT layer of the method for manufacturing the organic EL display device 50 according to the first embodiment.

As described above, in the organic EL display device including the TFT layer 30f according to this embodiment, between the pair of adjacent source line 18f and power supply line 18g, one end and the other end in the width direction of the lower gate line 12gf do not respectively partly overlap one end and the other end in the width direction of the gate line 16gf corresponding to one end and the other end of the lower gate line 12gf, because the gate line 16gf protrudes in the width direction further than the lower gate line 12gf, in a part between the pair of adjacent source line 18f and power supply line 18g. Thus, between the pair of adjacent source line 18f and power supply line 18g, the inclination of the side end of the interlayer insulating film 17 is relatively steep in the part in which one end and the other end in the width direction of the lower gate line 12gf overlap one end and the other end in the width direction of the gate line 16gf, whereas the inclination of the side end of the interlayer insulating film 17 is relatively gentle in the part in which one end and the other end in the width direction of the lower gate line 12gf do not overlap one end and the other end in the width direction of the gate line 16gf. Thus, when the third metal film, which is formed so as to cover the interlayer insulating film 17, undergoes patterning through dry etching, the film residue R may occur in the location in which the inclination of the side end of the interlayer insulating film 17 is relatively steep, whereas the film residue R is less likely to occur in the location in which the inclination of the side end of the interlayer insulating film 17 is relatively gentle. As a result, between the pair of adjacent source line 18f and power supply line 18g, the film residue R of the third metal film is less likely to be continuously formed in the direction in which the lower gate line 12gf and the gate line 16gf extend, so that a short circuit can be prevented between the pair of adjacent source line 18f and power supply line 18g. This can prevent a short circuit between the pair of adjacent source line 18f and power supply line 18g orthogonal to the lower gate line 12gf and gate line 16gf, on the interlayer insulating film 17 covering the gate line 16gf overlapping the lower gate line 12gf. It is noted that although this embodiment has described, by way of example, a wiring configuration that can prevent a short circuit between the pair of adjacent source line 18f and power supply line 18g, a short circuit can be prevented between the pair of adjacent source lines 18f when, for instance, the power supply lines 18g are formed in a layer (e.g., a layer between the protective insulating film 19 and flattening film 20) that is different from the layer including the source lines 18f.

### Sixth Embodiment

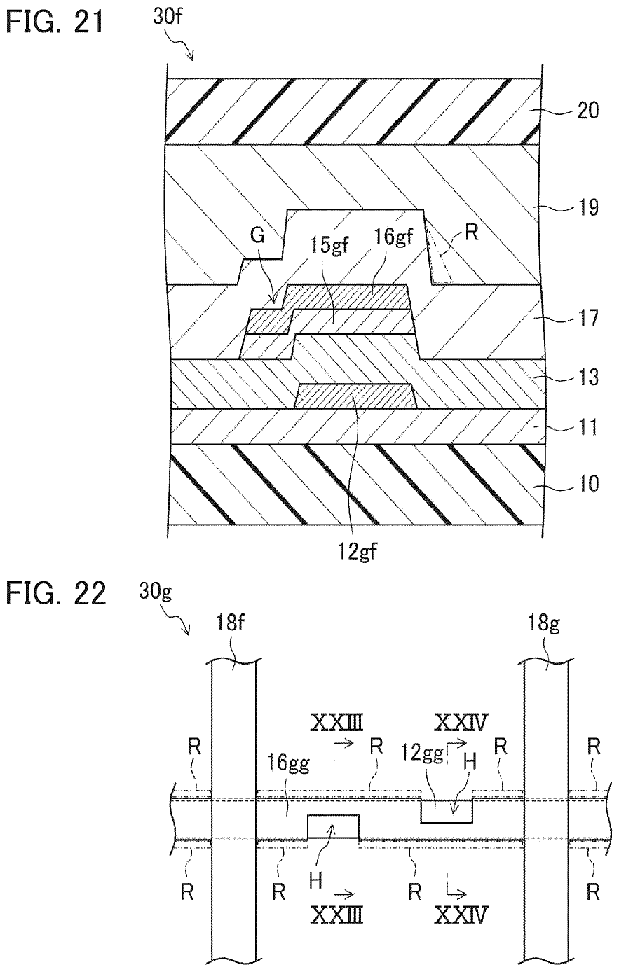

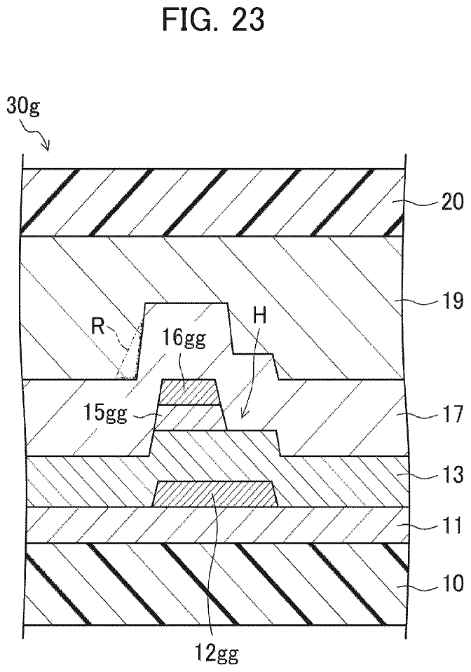

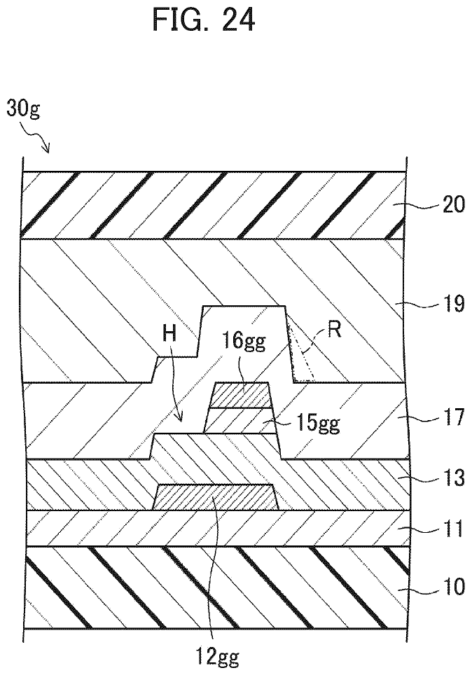

FIGS. 22 and 23 illustrate a display device according to a sixth embodiment of the disclosure. Here, FIG. 22 is a partial plan view of a TFT layer 30g constituting an organic EL display device according to this embodiment, and corresponds to FIG. 5 described in the first embodiment. In addition, FIGS. 23 and 24 are cross-sectional views of the TFT layer taken along lines XXIII-XXIII and XXIV-XXIV in FIG. 22.

The fifth embodiment has described, by way of example, the organic EL display device including the TFT layer 30f in which the gate line 16gf is provided so as to protrude sideward locally. This embodiment describes, by way of example, the organic EL display device including the TFT layer 30g in which a gate line 16gg is provided so as to be recessed sideward locally.

Like the organic EL display device 50 according to the first embodiment, the organic EL display device according to this embodiment includes the display device D for image display, and the frame region F provided around the display region D. The organic EL display device according to this embodiment also includes the following: the resin substrate 10 provided as a base substrate; the TFT layer 30g provided on the resin substrate 10; the organic EL element layer 40 provided as a light-emitting element layer on the TFT layer 30g; and the sealing film 45 provided on the organic EL element layer 40.

Like the TFT layer 30a according to the first embodiment, the TFT layer 30g includes the following: the base coat film 11 provided on the resin substrate 10; a plurality of first pixel TFTs 9a, a plurality of second pixel TFTs 9b, and a plurality of capacitors 9c provided on the base coat film 11; and the protective insulating film 19 and the flattening film 20 provided sequentially on the first pixel TFTs 9a, second pixel TFTs 9b, and capacitors 9c.

Like the TFT layer 30a according to the first embodiment, the TFT layer 30g includes a plurality of gate lines 16g (16gg) as a plurality of second wiring lines, and a plurality of lower gate lines 12g (12gg) as a plurality of first wiring lines. Like the TFT layer 30a according to the first embodiment, the TFT layer 30g also includes a plurality of source lines 18f and a plurality of power supply lines 18g as a plurality of third wiring lines. Like the TFT layer 30a according to the first embodiment, the TFT layer 30g also includes, in each subpixel P, the first pixel TFT 9a, the second pixel TFT 9b, and the capacitor 9c. Like the TFT layer 30a according to the first embodiment, the TFT layer 30g also includes the following sequentially stacked on the resin substrate 10: the base coat film 11; a first metal film, which constitutes the first gate electrode 12a and other components; the first gate insulating film 13 provided as a first inorganic insulating film; a semiconductor film, which constitutes the semiconductor layer 14a and other components; the second gate insulating film 15a and a second gate insulating film 15gg (see FIGS. 23 and 24) provided as a third inorganic insulating film; a second metal film, which constitutes the second gate electrode 16a and other components; the interlayer insulating film 17 provided as a second inorganic insulating film; a third metal film, which constitutes the source lines 18f, power supply lines 18g, and other components; the protective insulating film 19; and the flattening film 20.

Here, in this embodiment, as illustrated in FIGS. 22, 23 and 24, the lower gate line 12gg is shown as a specific example of the lower gate lines 12g, and the gate line 16gg is shown as a specific example of the gate lines 16g. It is noted that between the lower gate line 12gg and the gate line 16gg, the first gate insulating film 13 and the second gate insulating film 15gg are stacked sequentially from the lower gate line 12gg toward the gate line 16gg, as illustrated in FIGS. 23 and 24.

As illustrated in FIG. 22, the lower gate line 12gg is provided so as to extend straight in the lateral direction of the drawing with a constant width.

As illustrated in FIG. 22, the gate line 16gg includes, between the pair of adjacent source line 18f and power supply line 18g, a recess H provided at one end in its width direction and recessed in the width direction, and a recess H providing at the other end in its width direction and recessed in the width direction.

As illustrated in FIG. 22, between the pair of adjacent source line 18f and power supply line 18g, one end and the other end in the width direction of the lower gate line 12gg do not respectively partly overlap one end and the other end in the width direction of the gate line 16gg corresponding to one end and the other end of the lower gate line 12gg, because the recess H recessed toward the lower side of the drawing is provided at one end (i.e., the upper end of the drawing) in the width direction of the gate line 16gg, and the recess H recessed toward the upper side of the drawing is provided at the other end (i.e., the lower end of the drawing) in the width direction of the gate line 16gg. Thus, between the pair of adjacent source line 18f and power supply line 18g, the film residue R of the third metal film may occur in the part in which one end and the other end in the width direction of the lower gate line 12gg overlap one end and the other end in the width direction of the gate line 16gg because, as illustrated in FIGS. 23 and 24, the inclination of the side end of the interlayer insulating film 17 is relatively steep, whereas the film residue R of the third metal film can be less likely to occur in the part in which one end and the other end in the width direction of the lower gate line 12gg do not overlap one end and the other end in the width direction of the gate line 16gg because, as illustrated in FIGS. 23 and 24, the inclination of the side end of the interlayer insulating film 17 is relatively gentle.

It is noted that although this embodiment has described, by way of example, the TFT layer 30g including the recesses H in the gate line 16gg, the recesses H may be provided in the lower gate line 12gg. It is also noted that the fifth embodiment has described, by way of example, the TFT layer 30f in which the protrusions G are provided in the gate line 16gf, and this embodiment has described, by way of example, the TFT layer 30g in which the recesses H are provided in the gate line 16gg; in some embodiments, the protrusion G may be provided at one end in the width direction of at least one of the gate line 16gg and lower gate line 12gg, and the recess H may be provided at the other end in the width direction of at least one of the gate line 16gg and lower gate line 12gg.

Like the organic EL display device 50 according to the first embodiment, the organic EL display device including the TFT layer 30g with the foregoing configuration is configured such that the organic EL element 35 in each subpixel P emits light at a luminance level corresponding to a driving current, to display an image.

The organic EL display device including the TFT layer 30g according to this embodiment can be manufactured by changing the pattern shapes of the first and second metal films in the step of forming the TFT layer of the method for manufacturing the organic EL display device 50 according to the first embodiment.

As described above, in the organic EL display device including the TFT layer 30g according to this embodiment, between the pair of adjacent source line 18f and power supply line 18g, one end and the other end in the width direction of the lower gate line 12gg do not respectively partly overlap one end and the other end in the width direction of the gate line 16gg corresponding to one end and the other end of the lower gate line 12gg, because the gate line 16gg is recessed in the width direction further than the lower gate line 12gg, in a part between the pair of adjacent source line 18f and power supply line 18g. Thus, between the pair of adjacent source line 18f and power supply line 18g, the inclination of the side end of the interlayer insulating film 17 is relatively steep in the part in which one end and the other end in the width direction of the lower gate line 12gg overlap one end and the other end in the width direction of the gate line 16gg, whereas the inclination of the side end of the interlayer insulating film 17 is relatively gentle in the part in which one end and the other end in the width direction of the lower gate line 12gg do not overlap one end and the other end in the width direction of the gate line 16gg. Thus, when the third metal film, which is formed so as to cover the interlayer insulating film 17, undergoes patterning through dry etching, the film residue R may occur in the location in which the inclination of the side end of the interlayer insulating film 17 is relatively steep, whereas the film residue R is less likely to occur in the location in which the inclination of the side end of the interlayer insulating film 17 is relatively gentle. As a result, between the pair of adjacent source line 18f and power supply line 18g, the film residue R of the third metal film is less likely to be continuously formed in the direction in which the lower gate line 12gg and the gate line 16gg extend, so that a short circuit can be prevented between the pair of adjacent source line 18f and power supply line 18g. This can prevent a short circuit between the pair of adjacent source line 18f and power supply line 18g orthogonal to the lower gate line 12gg and gate line 16gg, on the interlayer insulating film 17 covering the gate line 16gg overlapping the lower gate line 12gg. It is noted that although this embodiment has described, by way of example, a wiring configuration that can prevent a short circuit between the pair of adjacent source line 18f and power supply line 18g, a short circuit can be prevented between the pair of adjacent source lines 18f when, for instance, the power supply lines 18g are formed in a layer (e.g., a layer between the protective insulating film 19 and flattening film 20) that is different from the layer including the source lines 18f.

### Other Embodiments

Although the foregoing embodiments have each described, by way of example, first pixel TFTs and second pixels TFT having a semiconductor layer containing an oxide semiconductor, the semiconductor layer constituting the first pixel TFTs and second pixel TFTs may contain polysilicon for instance, such as low-temperature polysilicon.

Although the foregoing embodiments have each described, by way of example, an organic EL layer having a five-ply stacked structure of a hole injection layer, a hole transport layer, an emission layer, an electron transport layer, and an electron injection layer, the organic EL layer may have, for instance, a three-ply stacked structure of a hole injection-and-transport layer, an emission layer, and an electron transport-and-injection layer.

Further, although the foregoing embodiments have each described, by way of example, an organic EL display device having a first electrode as an anode, and a second electrode as a cathode, the disclosure is also applicable to an organic EL display device with the stacked structure of its organic EL layer being inverted: a first electrode as a cathode, and a second electrode as an anode.

Further, although the foregoing embodiments have each described, by way of example, an organic EL display device in which a TFT's electrode connected to the first electrode constitutes a drain electrode, the disclosure is also applicable to an organic EL display device in which a TFT's electrode connected to the first electrode constitutes a source electrode.

Further, although the foregoing embodiments have each described an organic EL display device as a display device by way of example, the disclosure is applicable to a display device provided with a plurality of light-emitting elements that are driven by current; for instance, the disclosure is applicable to a display device provided with quantum-dot light-emitting diodes (QLEDs), which are light-emitting elements including a quantum-dot-containing layer.

Further, in the disclosure, the constituent elements in the individual embodiments may be combined in any manner unless otherwise departing from the purport of the individual embodiments.

### Industrial Applicability

As described above, the disclosure is useful for flexible display devices.

1. A display device comprising:
a base substrate; and
a thin-film transistor layer provided on the base substrate, and including a stack of, in sequence, a first metal film, a first inorganic insulating film, a second metal film, a second inorganic insulating film, and a third metal film,
the thin-film transistor layer including
a plurality of first wiring lines extending in parallel with each other in the first metal film,
a plurality of second wiring lines extending in parallel with each other in the second metal film, and overlapping the plurality of first wiring lines, and
a plurality of third wiring lines extending in parallel with each other in the third metal film, and intersecting with the plurality of first wiring lines and the plurality of second wiring lines,
wherein between a pair of adjacent third wiring lines, one end and another end in a width direction of each of the plurality of first wiring lines do not respectively partly overlap one end and another end in a width direction of a corresponding one of the plurality of second wiring lines corresponding to the one end and the another end of each of the plurality of first wiring lines, the pair of adjacent third wiring lines being included in the plurality of third wiring lines.

2.-8. (canceled)

9. The display device according to claim 1, wherein
between the first inorganic insulating film and the second metal film, a semiconductor film and a third inorganic insulating film are stacked sequentially from the first inorganic insulating film toward the second metal film,
the thin-film transistor layer includes a pixel thin-film transistor in each of subpixels constituting a display region, and
the pixel thin-film transistor includes
a semiconductor layer formed from the semiconductor film,
a first gate electrode formed from the first metal film, and
a second gate electrode formed from the second metal film.

10. The display device according to claim 9, wherein the semiconductor film contains an oxide semiconductor.

11. The display device according to claim 1, comprising:
a light-emitting element layer provided on the thin-film transistor layer, and including a plurality of light-emitting elements arranged in correspondence with a plurality of subpixels constituting a display region; and
a sealing film provided on the light-emitting element layer.

12. The display device according to claim 11, wherein each of the plurality of light-emitting elements is an organic electroluminescence element.

13. A display device comprising:
a base substrate; and
a thin-film transistor layer provided on the base substrate, and including a stack of, in sequence, a first metal film, a first inorganic insulating film, a second metal film, a second inorganic insulating film, and a third metal film,
the thin-film transistor layer including
a plurality of first wiring lines extending in parallel with each other in the first metal film,
a plurality of second wiring lines extending in parallel with each other in the second metal film, and overlapping the plurality of first wiring lines, and
a plurality of third wiring lines extending in parallel with each other in the third metal film, and intersecting with the plurality of first wiring lines and the plurality of second wiring lines,
wherein between a pair of adjacent third wiring lines, one end and another end in a width direction of each of the plurality of first wiring lines do not respectively partly overlap one end and another end in a width direction of a corresponding one of the plurality of second wiring lines corresponding to the one end and the another end of each of the plurality of first wiring lines, the pair of adjacent third wiring lines being included in the plurality of third wiring lines, and
in a middle between the pair of adjacent third wiring lines,
(A) each of the plurality of second wiring lines is provided so as to flex once in a direction in which each of the plurality of third wiring lines extends, and
a portion of each of the plurality of second wiring lines protruding, in a plan view, from a corresponding one of the plurality of first wiring lines changes a protrusion direction in the middle,
(B) each of the plurality of first wiring lines is provided so as to flex once in a direction in which each of the plurality of third wiring lines extends, and
a portion of each of the plurality of first wiring lines protruding, in a plan view, from the corresponding one of the plurality of second wiring lines changes a protrusion direction in the middle.

14. The display device according to claim 13, wherein
between the first inorganic insulating film and the second metal film, a semiconductor film and a third inorganic insulating film are stacked sequentially from the first inorganic insulating film toward the second metal film,
the thin-film transistor layer includes a pixel thin-film transistor in each of subpixels constituting a display region, and
the pixel thin-film transistor includes
a semiconductor layer formed from the semiconductor film,
a first gate electrode formed from the first metal film, and
a second gate electrode formed from the second metal film.

15. The display device according to claim 14, wherein the semiconductor film contains an oxide semiconductor.

16. The display device according to claim 13, comprising:
a light-emitting element layer provided on the thin-film transistor layer, and including a plurality of light-emitting elements arranged in correspondence with a plurality of subpixels constituting a display region; and
a sealing film provided on the light-emitting element layer.

17. The display device according to claim 16, wherein each of the plurality of light-emitting elements is an organic electroluminescence element.

18. A display device comprising:
a base substrate; and
a thin-film transistor layer provided on the base substrate, and including a stack of, in sequence, a first metal film, a first inorganic insulating film, a second metal film, a second inorganic insulating film, and a third metal film,
the thin-film transistor layer including
a plurality of first wiring lines extending in parallel with each other in the first metal film,
a plurality of second wiring lines extending in parallel with each other in the second metal film, and overlapping the plurality of first wiring lines, and
a plurality of third wiring lines extending in parallel with each other in the third metal film, and intersecting with the plurality of first wiring lines and the plurality of second wiring lines,
wherein between a pair of adjacent third wiring lines, one end and another end in a width direction of each of the plurality of first wiring lines do not respectively partly overlap one end and another end in a width direction of a corresponding one of the plurality of second wiring lines corresponding to the one end and the another end of each of the plurality of first wiring lines, the pair of adjacent third wiring lines being included in the plurality of third wiring lines,
in a middle between the pair of adjacent third wiring lines, each of the plurality of first wiring lines is provided so as to flex once in a direction in which each of the plurality of third wiring lines extends,
in a middle between the pair of adjacent third wiring lines, each of the plurality of second wiring lines is provided so as to flex once in the direction in which each of the plurality of third wiring lines extends, and
in a portion of overlap between the first wiring line and the second wiring line, the first wiring line and the second wiring line flex in mutually different directions when viewed from one side to another side in a length direction.

19. The display device according to claim 18, wherein
between the first inorganic insulating film and the second metal film, a semiconductor film and a third inorganic insulating film are stacked sequentially from the first inorganic insulating film toward the second metal film,
the thin-film transistor layer includes a pixel thin-film transistor in each of subpixels constituting a display region, and
the pixel thin-film transistor includes
a semiconductor layer formed from the semiconductor film,
a first gate electrode formed from the first metal film, and
a second gate electrode formed from the second metal film.

20. The display device according to claim 19, wherein the semiconductor film contains an oxide semiconductor.

21. The display device according to claim 18, comprising:
a light-emitting element layer provided on the thin-film transistor layer, and including a plurality of light-emitting elements arranged in correspondence with a plurality of subpixels constituting a display region; and
a sealing film provided on the light-emitting element layer.

22. The display device according to claim 21, wherein each of the plurality of light-emitting elements is an organic electroluminescence element.
